(19) United States
(12) Patent Application Publication
(10) Pub. No.: US 2010/0044773 A1
(43) Pub. Date: Feb. 25, 2010

(54) SEMICONDUCTOR MEMORY DEVICE

(75) Inventors: Yoshiyuki Ishigaki, Tokyo (JP); Naoki Tsuji, Tokyo (JP); Hisakazu Otoi, Tokyo (JP); Hiroki Mukai, Itami (JP); Yuichi Kunori, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/495,093

(22) Filed: Jun. 30, 2009

(30) Foreign Application Priority Data
Aug. 20, 2008 (JP) 2008-211804

(51) Int. Cl. H01L 29/788

(52) U.S. Cl. 257/320; 257/E29.3

(57) ABSTRACT

To provide a semiconductor memory device having an improved write efficiency because deterioration of a gate insulating film is suppressed.

An element formation region is formed in a region of a semiconductor substrate sandwiched between element isolation regions. In the element isolation regions, a silicon oxide film is filled in a trench having a predetermined depth. An erase gate electrode is formed in the element isolation region while being buried in the silicon oxide film. Over the element formation region, floating gate electrodes are formed via a gate oxide film and control gate electrodes are formed over the floating gate electrodes via an ONO film. Two adjacent floating gate electrodes have therebetween an insulating film formed to cover the erase gate electrode.

### CROSS-REFERENCE TO RELATED APPLICATIONS

The disclosure of Japanese Patent Application No. 2008-211804 filed on Aug. 20, 2008 including the specification, drawings and abstract is incorporated herein by reference in its entirety.

### BACKGROUND OF THE INVENTION

The present invention relates to a semiconductor memory device, in particular, to a semiconductor memory device equipped with an erase gate electrode.

A flash memory is one of electrically programmable nonvolatile memories. In typical NOR type flash memories, programming is performed using a channel hot electron (CHE) writing system, while erasing is performed using a substrate FN (Fowler-Nordheim) erasing system. Documents disclosing NOR type flash memories include, for example, Patent Document 1.

### [Patent Document 1] Japanese Unexamined Patent Publication No. 2006-5372

### SUMMARY OF THE INVENTION

In conventional flash memories, however, reduction in a writing time and thereby improvement in a write efficiency are required. In addition, in an erase operation, deterioration of a gate insulating film occurs due to extraction of electrons accumulated in a floating gate electrode into the side of a semiconductor substrate via the gate insulating film immediately below the floating gate electrode so that suppression of this deterioration is also required.

An object of the invention is to provide a semiconductor memory device capable of suppressing deterioration of its gate insulating film and having an improved write efficiency.

The semiconductor memory device according to the invention is equipped with a first element isolation region, a second element isolation region, a floating gate electrode, a control gate electrode, a pair of impurity regions having a predetermined conductivity type, and an erase gate electrode. The first element isolation region and the second element isolation region extend in a first direction in a first region of a semiconductor substrate having a principal surface and are separated from each other with a space therebetween in a second direction crossing the first direction. The floating gate electrode is formed, via a first insulating film, over a predetermined region in an element formation region of the semiconductor substrate sandwiched between the first element isolation region and the second element isolation region. The control gate electrode extends in the second direction and is formed over the floating gate electrode via a film stack containing a silicon oxide film and a silicon nitride film. The pair of impurity regions having a predetermined conductivity type is formed in the element formation region at both side portions with the floating gate electrode and the control gate electrode therebetween. The erase gate electrode is formed along the first direction while being buried inside the first element isolation region.

According to the semiconductor memory device of the invention, the erase gate electrode is formed along the first direction while being buried inside the first element isolation region. Since, in an erase operation, electrons accumulated in the floating gate electrode are extracted from the erase gate electrode formed in the first element isolation region, deterioration of the first insulating film can be suppressed compared with a substrate FN erase in which electrons accumulated in the floating gate electrode are extracted via a gate insulating film placed immediately below the floating gate electrode.

### BRIEF DESCRIPTION OF THE DRAWINGS

FIG. 1 is a circuit diagram of a memory cell in a flash memory relating to Embodiment 1 of the invention;

FIG. 2 is a fragmentary plan view illustrating the positional relationship among an element isolation region, a control gate electrode, and the like in the memory cell in Embodiment 1;

FIG. 3 is a fragmentary plan view illustrating the positional relationship between a bit line and a source line in the memory cell in Embodiment 1;

FIG. 4 is a fragmentary cross-sectional view taken along a cross-section line IV-IV of FIG. 2 in Embodiment 1;

FIG. 5 is a fragmentary schematic view illustrating the cross-sectional structure taken along a cross-section line V-V of FIG. 2 in Embodiment 1;

FIG. 6 illustrates each member for describing write, erase and read operations of the flash memory and voltage to be applied thereto in Embodiment 1;

FIG. 7 is a cross-sectional schematic view for describing the write operation of the flash memory in Embodiment 1;

FIG. 8 is a cross-sectional schematic view for describing the erase operation of the flash memory in Embodiment 1;

FIG. 9 is a cross-sectional view illustrating a step of a manufacturing method of the flash memory in Embodiment 1;

FIG. 10 is a cross-sectional view illustrating a step to be performed subsequent to the step of FIG. 9 in Embodiment 1;

FIG. 11 is a cross-sectional view illustrating a step to be performed subsequent to the step of FIG. 10 in Embodiment 1;

FIG. 12 is a cross-sectional view illustrating a step to be performed subsequent to the step of FIG. 11 in Embodiment 1;

FIG. 13 is a cross-sectional view illustrating a step to be performed subsequent to the step of FIG. 12 in Embodiment 1;

FIG. 14 is a cross-sectional view illustrating a step to be performed subsequent to the step of FIG. 13 in Embodiment 1;

FIG. 15 is a cross-sectional view illustrating a step to be performed subsequent to the step of FIG. 14 in Embodiment 1;

FIG. 16 is a cross-sectional view illustrating a step to be performed subsequent to the step of FIG. 15 in Embodiment 1;

FIG. 17 is a cross-sectional view illustrating a step to be performed subsequent to the step of FIG. 16 in Embodiment 1;

FIG. 18 is a cross-sectional view illustrating a step to be performed subsequent to the step of FIG. 17 in Embodiment 1;

FIG. 19 is a cross-sectional view illustrating a step to be performed subsequent to the step of FIG. 18 in Embodiment 1;

FIG. 20 is a cross-sectional view illustrating a step to be performed subsequent to the step of FIG. 19 in Embodiment 1;

FIG. 21 is a cross-sectional view illustrating a step to be performed subsequent to the step of FIG. 20 in Embodiment 1;

FIG. 22 is a cross-sectional view illustrating a step to be performed subsequent to the step of FIG. 21 in Embodiment 1;

FIG. 23 is a cross-sectional view illustrating a step to be performed subsequent to the step of FIG. 22 in Embodiment 1;

FIG. 24 is a cross-sectional view illustrating a step to be performed subsequent to the step of FIG. 23 in Embodiment 1;

FIG. 25 is a cross-sectional view illustrating a step to be performed subsequent to the step of FIG. 24 in Embodiment 1;

FIG. 26 is a cross-sectional view illustrating a step to be performed subsequent to the step of FIG. 25 in Embodiment 1;

FIG. 27 is a cross-sectional view illustrating a step to be performed subsequent to the step of FIG. 26 in Embodiment 1;

FIG. 28 is a cross-sectional view illustrating a step to be performed subsequent to the step of FIG. 27 in Embodiment 1;

FIG. 29 is a cross-sectional view illustrating a step of a manufacturing method of a semiconductor device relating to a modification example in Embodiment 1;

FIG. 30 is a cross-sectional view illustrating a step to be performed subsequent to the step of FIG. 29 in Embodiment 1;

FIG. 31 is a cross-sectional view illustrating a step to be performed subsequent to the step of FIG. 30 in Embodiment 1;

FIG. 32 is a fragmentary cross-sectional view corresponding to a cross-section line XXXII-XXXII of FIG. 2 in the step of FIG. 21 in Embodiment 1;

FIG. 33 is a first fragmentary cross-sectional view for describing the capacitance of the floating gate electrode and the erase gate electrode in Embodiment 1;

FIG. 34 is a second fragmentary cross-sectional view for describing the capacitance of the floating gate electrode and the erase gate electrode in Embodiment 1;

FIG. 35 is a fragmentary plan view illustrating the positional relationship among an element isolation region, a control gate electrode, and the like in a memory cell of a flash memory relating to Embodiment 2 of the invention;

FIG. 36 is a fragmentary plan view illustrating the positional relationship between a bit line and a source line in the memory cell in Embodiment 2;

FIG. 37 is a fragmentary cross-sectional view taken along a cross-section line XXXVII-XXXVII of FIG. 35 in Embodiment 2;

FIG. 38 is a fragmentary schematic view illustrating the cross-sectional structure taken along a cross-section line XXXVIII-XXXVIII of FIG. 35 in Embodiment 2;

FIG. 39 illustrates members for describing the write, erase and read operations of the flash memory and a voltage applied thereto in Embodiment 2;

FIG. 40 is a fragmentary plan view illustrating the positional relationship among an element isolation region, a control gate electrode, and the like in a memory cell of a flash memory relating to Embodiment 3 of the invention;

FIG. 41 is a fragmentary plan view illustrating the positional relationship between a bit line and a source line in the memory cell in Embodiment 3;

FIG. 42 is a fragmentary cross-sectional view taken along a cross-section line XLII-XLII of FIG. 40 in Embodiment 3;

FIG. 43 is a fragmentary schematic view illustrating a cross-sectional structure taken along a cross-section line XLIII-XLIII of FIG. 40 in Embodiment 3; and

FIG. 44 illustrates members for describing the write, erase and read operations of the flash memory and a voltage applied thereto in Embodiment 3.

### DETAILED DESCRIPTION OF THE PREFERRED EMBODIMENTS

### Embodiment 1

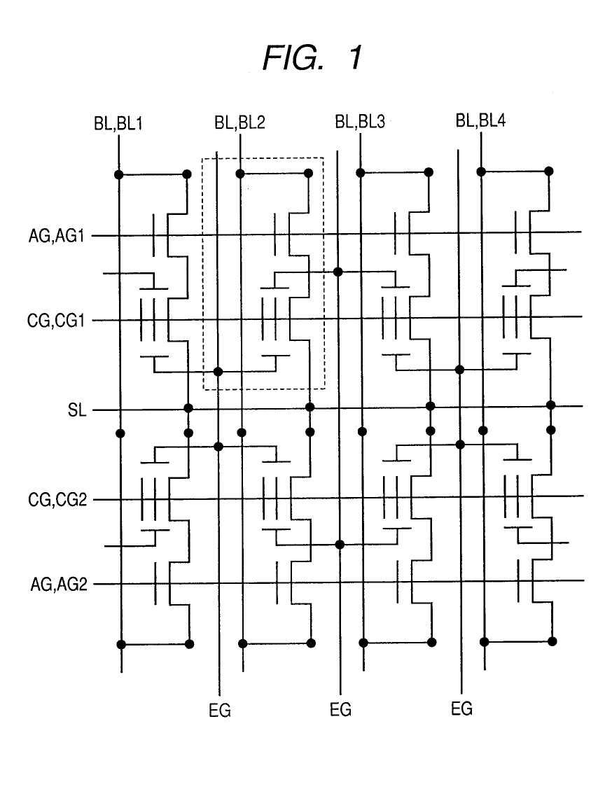

A description will hereinafter be made of a NOR type flash memory equipped with an assist gate electrode. An equivalent circuit of the memory cell is shown in FIG. 1. As illustrated in FIG. 1, a plurality of memory cells is arranged in a matrix form and control gate electrodes (lines) CG, CG1, CG2, and the like, assist gate electrodes (lines) AG, AG1, AG2, and the like, and a source line SL are formed in a row direction (lateral direction). Control gate electrodes (lines) of the memory cell arranged in a row direction are electrically coupled to the control gate electrodes (lines) CG, CG1, CG2 and the like; assist gate electrodes (lines) are electrically coupled to the assist gate electrodes (lines) AG, AG1, AG2, and the like; and a source region of the memory cell is electrically coupled to the source line SL.

In a column direction (longitudinal direction) substantially perpendicular to the row direction, bit lines BL, BL1 to BL4, and the like and erase gate electrodes (lines) EG are formed. A drain region of the memory cell arranged in a column direction is electrically coupled to the bit lines BL, BL1 to BL4, and the like. As will be described later, the erase gate electrodes (lines) are formed in a silicon oxide film of an element isolation region. In FIG. 1, a region surrounded by a dotted line corresponds to one memory cell.

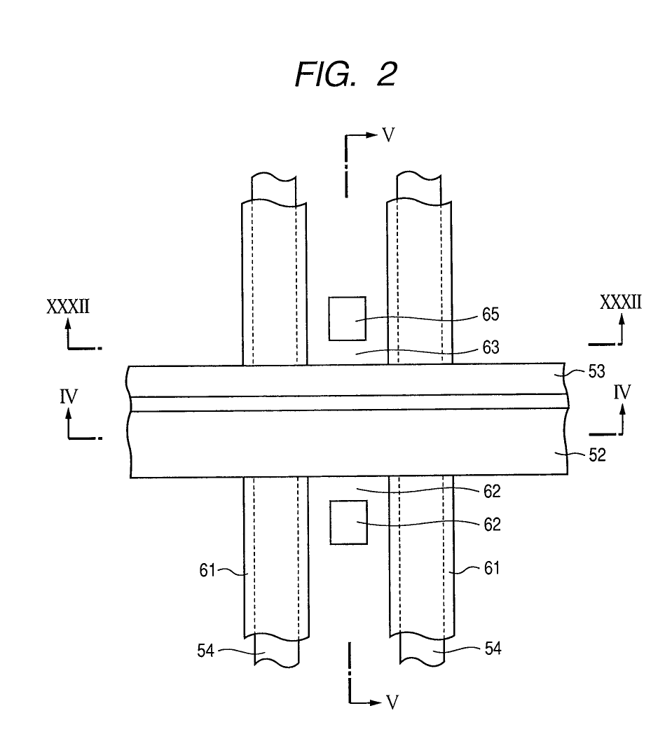

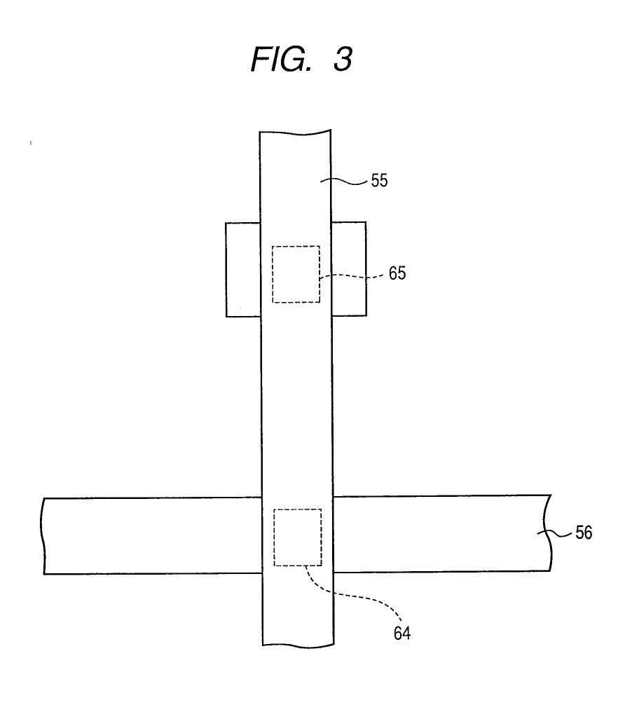

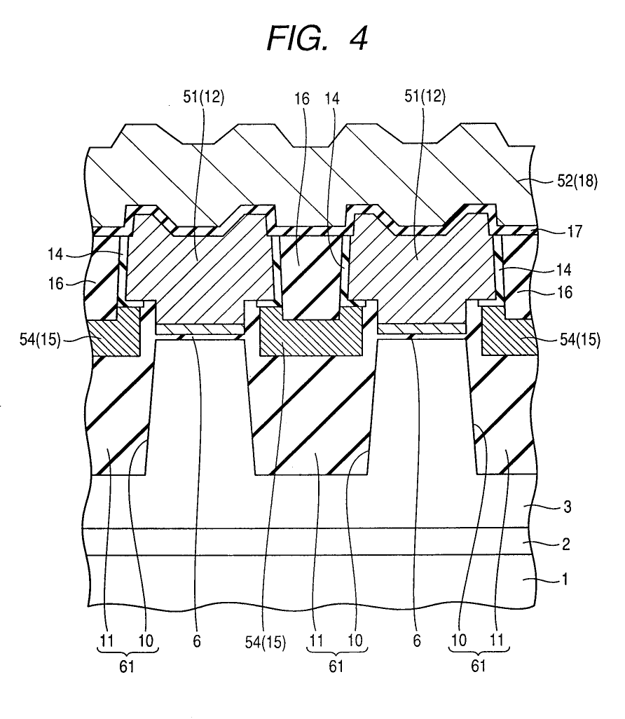

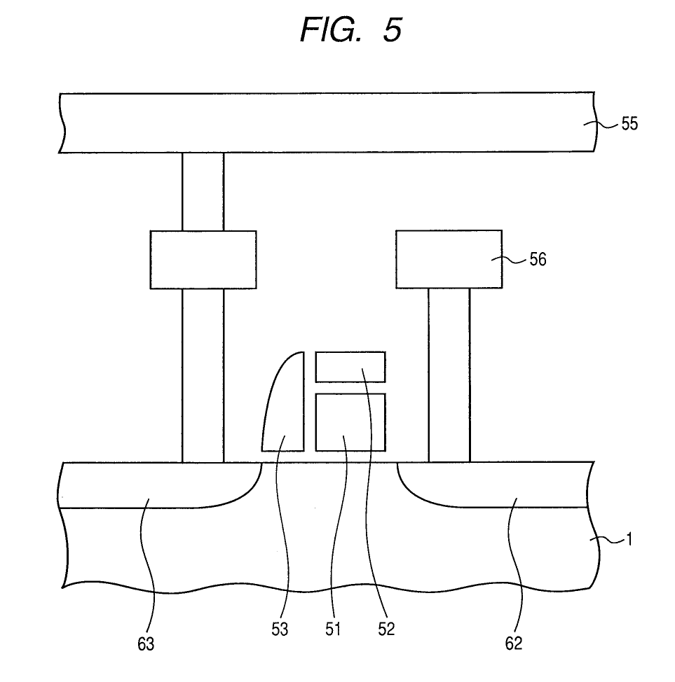

The structure of the memory cell will next be described. As illustrated in FIGS. 2, 3, 4, and 5, element isolation regions 61 separated from each other with a space are formed in the principal surface of a semiconductor substrate 1. An element formation region is formed in a region of the semiconductor substrate sandwiched between the two element isolation regions 61 and 61. In each element isolation region 61, a silicon oxide film 11 is filled, as an isolation insulating film, in a trench 10 formed in the semiconductor substrate 1 to have a predetermined depth. In the present flash memory, an erase gate electrode 54 is formed in the element isolation region 61 while being buried inside the silicon oxide film 11.

A floating gate electrode 51 is formed over the element formation region with a gate oxide film 6 interposed therebetween. A control gate electrode 52 is formed over the floating gate electrode 51 with an ONO film 17 interposed therebetween. The term “ONO film” means a film stack of a silicon oxide film, a silicon nitride film, and a silicon oxide film. A silicon oxide film 14 is formed over the surface of the floating gate electrode 51 and between two adjacent floating gate electrodes 51 and 51, an insulating film 16 made of, for example, a silicon oxide film is formed so as to cover therewith the erase gate electrode 54.

The control gate electrode 52 is formed in a direction crossing an extending direction of the element isolation region 61. Over the side surface of either one of the control gate electrode 52 and the floating gate electrode 51, an assist gate electrode 53 is formed. The assist gate electrode 53 is electrically insulated from the control gate electrode 52 and the floating gate electrode 51.

A source region 62 is formed in one of the element formation regions located at both sides, with the floating gate electrode 51 and the control gate electrode 52 sandwiched therebetween, while a drain region 63 is formed in the other region. A source line 56 is coupled to the source region 62 via a source contact 64. A bit line 55 is coupled to the drain region 63 via a drain contact 65. The source contact 64 and the drain contact 65 are each a common contact to two cells adjacent to each other.

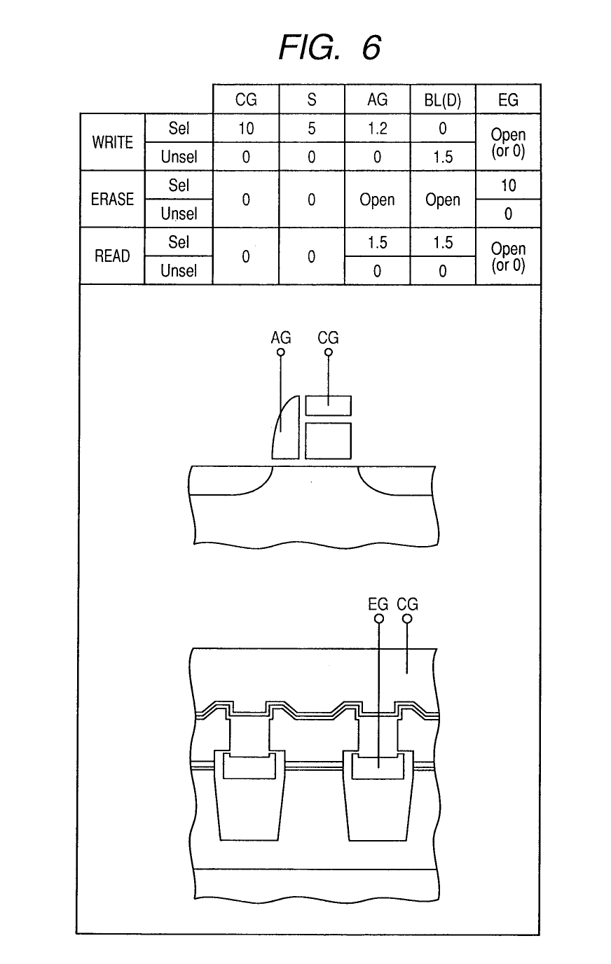

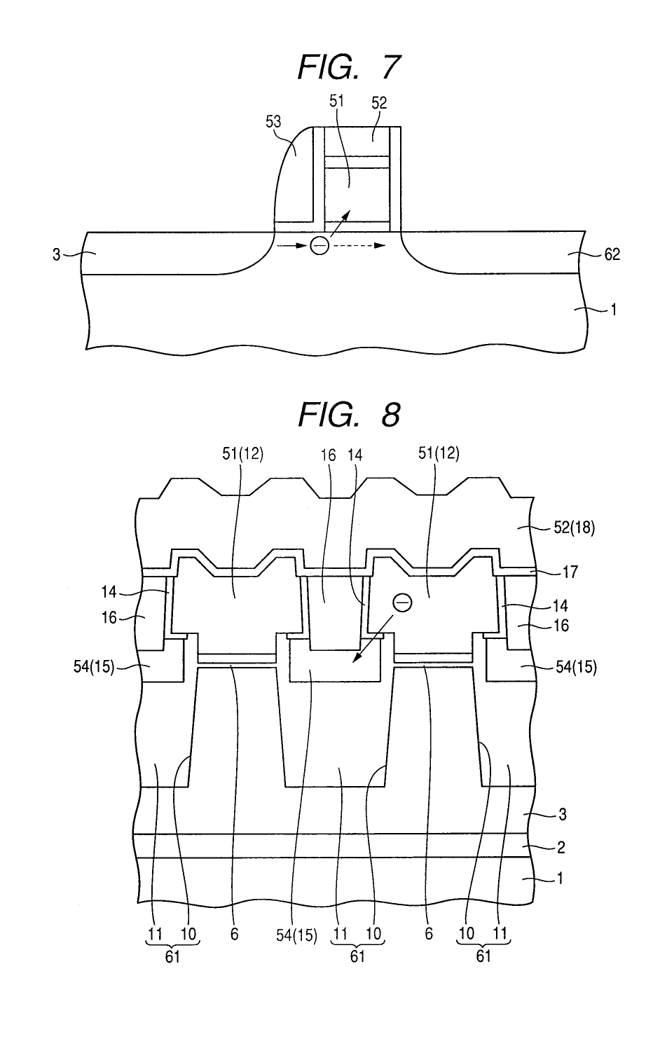

Next, the operation of the present flash memory will be described. Upon a write operation, by applying 10V to the control gate electrode (CG) of the selected cell, 5V to the source line (S), 1.2V to the assist gate electrode (AG) and 0V to the bit line (BL) and bringing the erase gate electrode (EG) to an open state or applying 0V to it as illustrated in FIG. 6, electrons are accumulated as data in the floating gate electrode 51 due to the source side injection caused by a voltage applied to the assist gate electrode as illustrated in FIG. 7.

Upon an erase operation, by applying 0V to the control gate electrode (CG) of the selected cell and 0V to the source line (S), bringing the assist gate electrode (AG) and the bit line (BL) to an open state, and applying 10V to the erase gate electrode (EG), electrons in the floating gate electrode 51 are extracted into the erase gate electrode 54 formed in the silicon oxide film 11 in the element isolation region 61 as illustrated in FIG. 8.

A read operation is performed by judging whether a current flows or not by applying 0V to the control gate electrode (CG) of the selected cell, 0V to the source line (S), 1.5V to the assist gate electrode (AG), and 1.5V to the bit line (BL) and bringing the erase gate electrode (EG) to an open state or applying 0V thereto.

In the above flash memory, the erase gate electrode 54 is formed in the element isolation region 61 while the erase gate electrode 54 is buried in the silicon oxide film 11 filled in the trench 10. This makes it possible, upon the erase operation, extract the electrons accumulated in the floating gate electrode 51 into the erase gate electrode 54 formed in the element isolation region (refer to FIG. 8). As a result, compared with substrate FN erase in which electrons accumulated in a floating gate electrode are extracted into a semiconductor substrate via a gate insulating film located immediately below the floating gate electrode, deterioration of the gate oxide film 6 can be suppressed. In addition, the thickness of the gate oxide film 6 can be determined without being limited by an erase rate.

In the above flash memory, the assist gate electrode 53 is formed over the side surface of either one of the floating gate electrode 51 and the control gate electrode 52. This structure enables to write data by making use of source side injection in the write operation (refer to FIG. 7). As a result, improvement in write efficiency and shortening of write time can be realized.

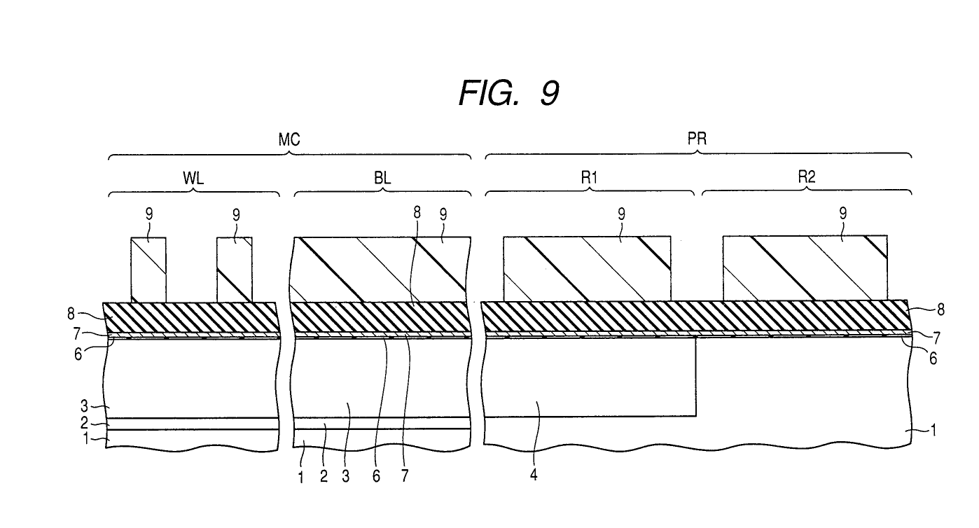

A manufacturing method of the above flash memory will next be described. First, as illustrated in FIG. 9, an N type buried well 2 and a P well 3 are formed in a memory cell region MC of a semiconductor substrate 1 in which a memory cell is to be formed. In a peripheral circuit region PR in which a logic circuit for controlling the memory cell and the like are to be formed, an N well 4 is formed. A gate oxide film 6 is then formed over the principal surface of the semiconductor substrate 1. A non-doped amorphous silicon film 7 is then formed over the gate oxide film 6.

A silicon nitride film 8 is formed over the amorphous silicon film 7. A predetermined resist pattern 9 for forming a trench is formed over the silicon nitride film 8. In the memory cell region MC in FIG. 9, WL is a cross-sectional structure in a direction of a control gate electrode (line), while BL is a cross-sectional structure in a direction of a bit line. In the peripheral circuit region PR, R1 is a cross-sectional structure of a PMOS region, while R2 is a cross-sectional structure of an NMOS region.

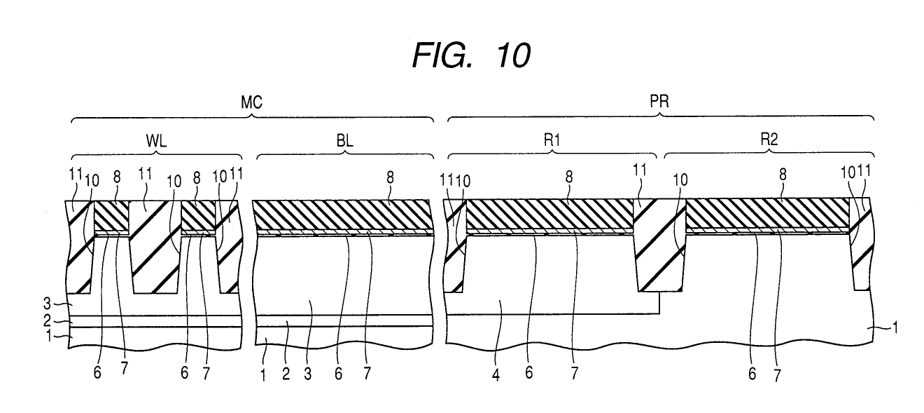

With the resist pattern 9 as a mask, the silicon nitride film 8 and the semiconductor substrate 1 are etched to form a trench 10 (refer to FIG. 10). The resist pattern 9 is then removed. A silicon oxide film (not illustrated) is formed over the silicon nitride film 8 to fill the trench 10. Then, as illustrated in FIG. 10, the silicon oxide film is subjected to chemical mechanical polishing treatment to remove a portion of the silicon oxide film from the upper surface of the silicon nitride film 8 while leaving the portion of the silicon oxide film 11 in the trench 10.

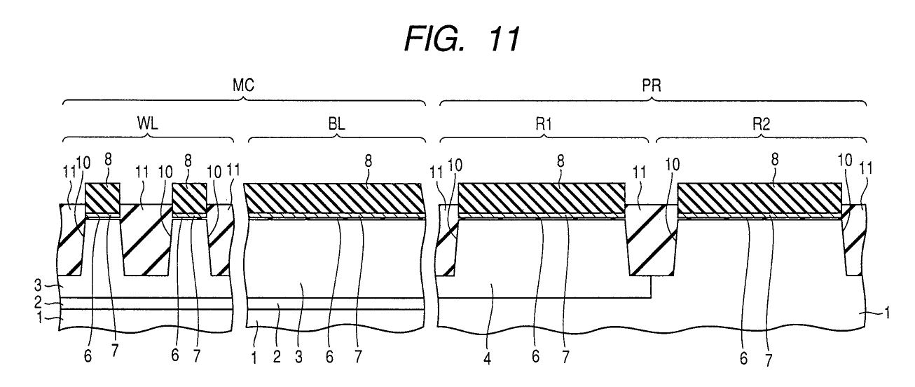

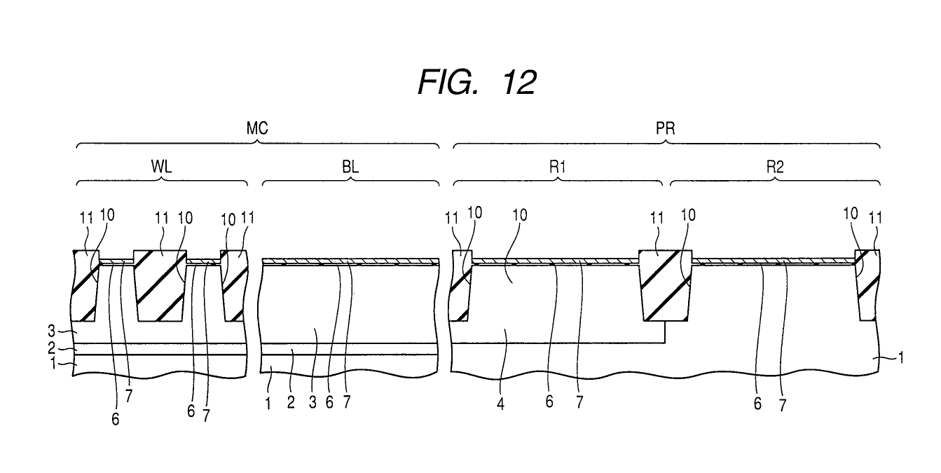

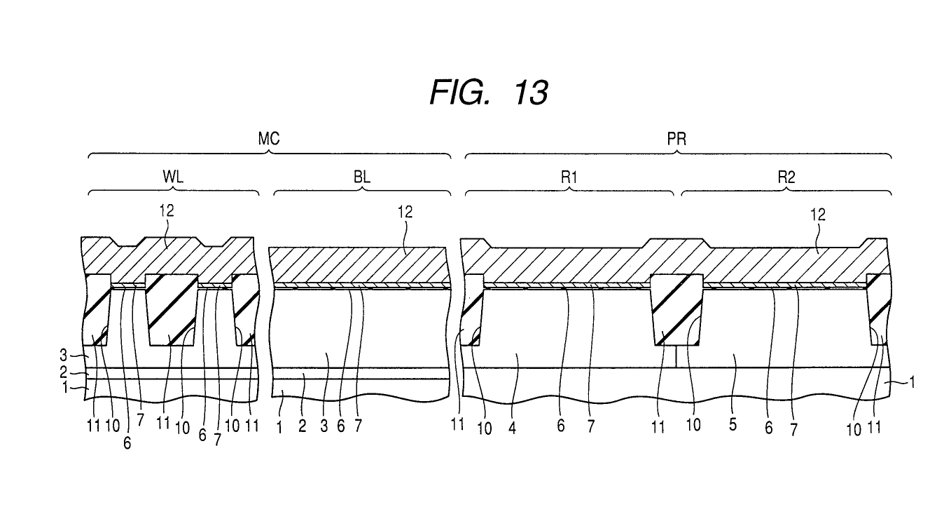

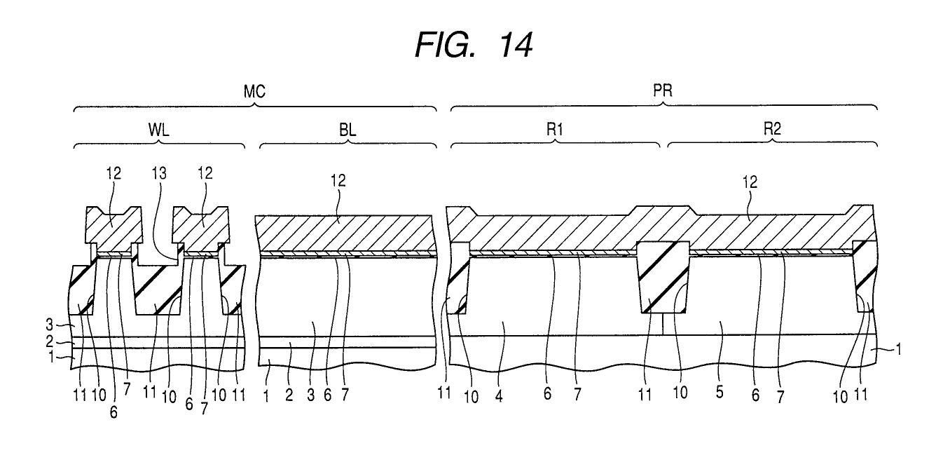

As illustrated in FIG. 11, wet etching is performed to lower the position (height) of the surface of the silicon oxide film 11. As illustrated in FIG. 12, the silicon nitride film 8 is removed by wet etching. Then, as illustrated in FIG. 13, a P well 5 is formed in the NMOS region. A polysilicon film 12 is then formed over the semiconductor substrate 1. A resist pattern (not illustrated) is formed over the polysilicon film 12. With this resist pattern as a mask, the polysilicon film 12 is anisotropically etched to expose the surface of the silicon oxide film 11 in the trench 10 in the memory cell region. The silicon oxide film 11 thus exposed is then subjected to anisotropic etching and isotropic etching to form an opening portion 13 for forming an erase gate electrode as illustrated in FIG. 14. The resist pattern is then removed.

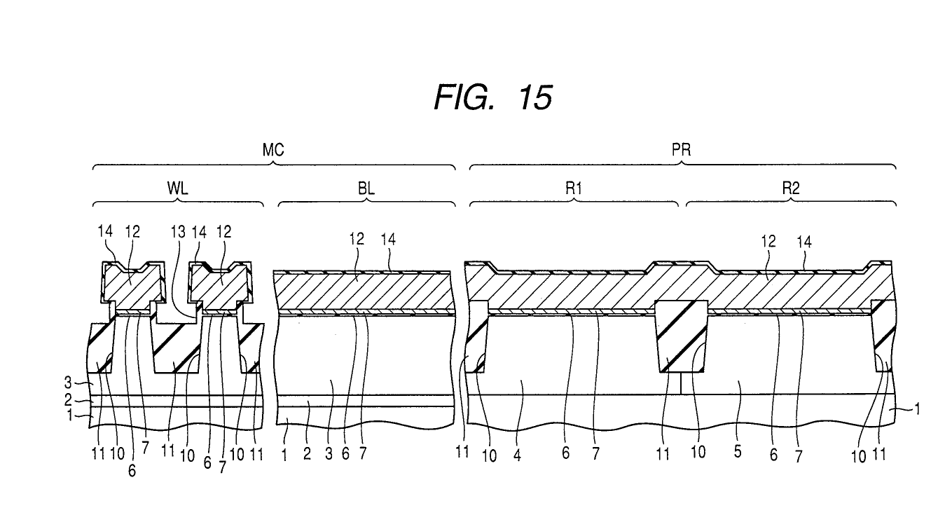

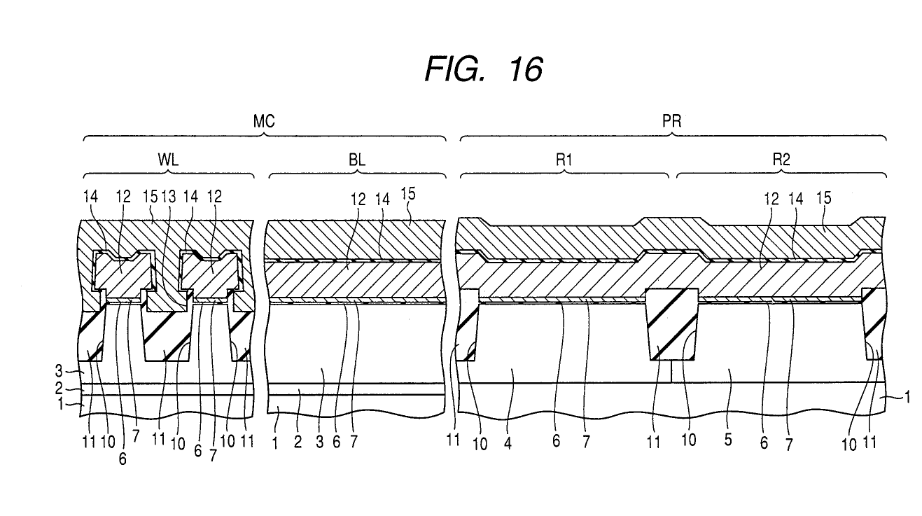

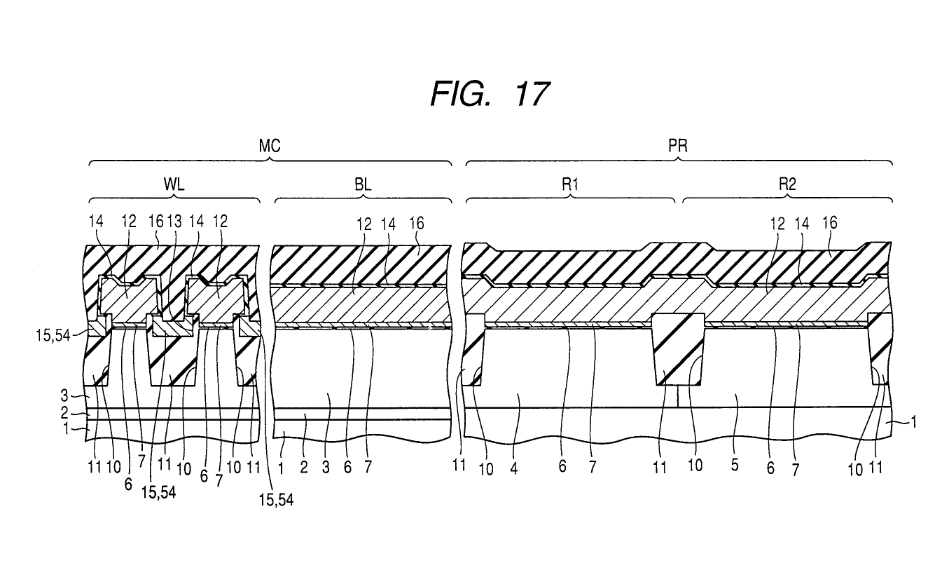

Then, as illustrated in FIG. 15, thermal oxidation treatment is given to form a silicon oxide film 14 over the surface of the polysilicon film 12. As illustrated in FIG. 16, a polysilicon film 15 is then formed over the semiconductor substrate 1 to fill therewith the opening portion 13 formed in the element isolation region of the memory cell region MC. As illustrated in FIG. 17, the polysilicon film 15 is etched back to leave a portion of the polysilicon film 15 in the opening portion 13 and remove the other portion of the polysilicon film 15. Then, an insulating film 16 made of, for example, a TEOS (Tetra Ethyl Ortho Silicate glass) silicon oxide film is formed over the semiconductor substrate 1 to cover the remaining portion of the polysilicon film 15.

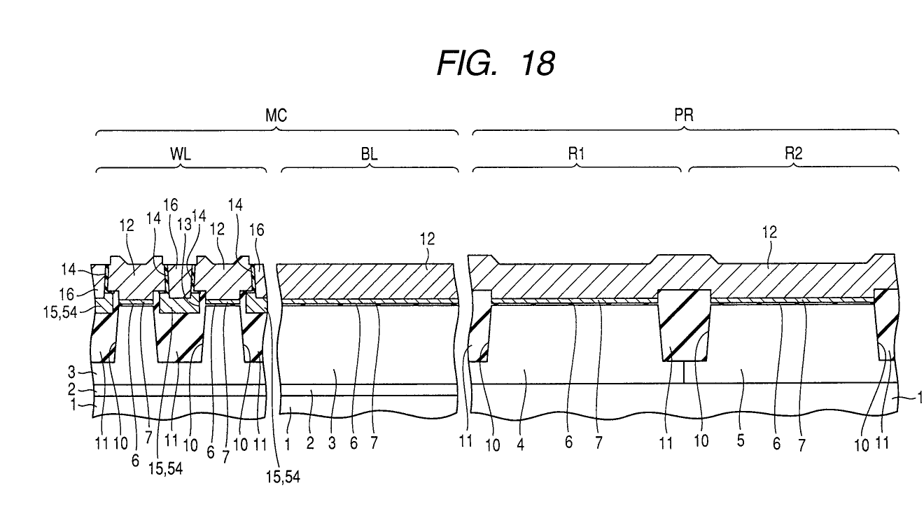

As illustrated in FIG. 18, the insulating film 16 is subjected to etch back treatment or chemical mechanical polishing treatment to leave a portion of the silicon oxide films 16 and 14 located between the polysilicon films 12 and 12 which will be floating gate electrodes adjacent to each other and immediately above the polysilicon film 15 which will be the erase gate electrode and remove the other portion of the silicon oxide films 16 and 14.

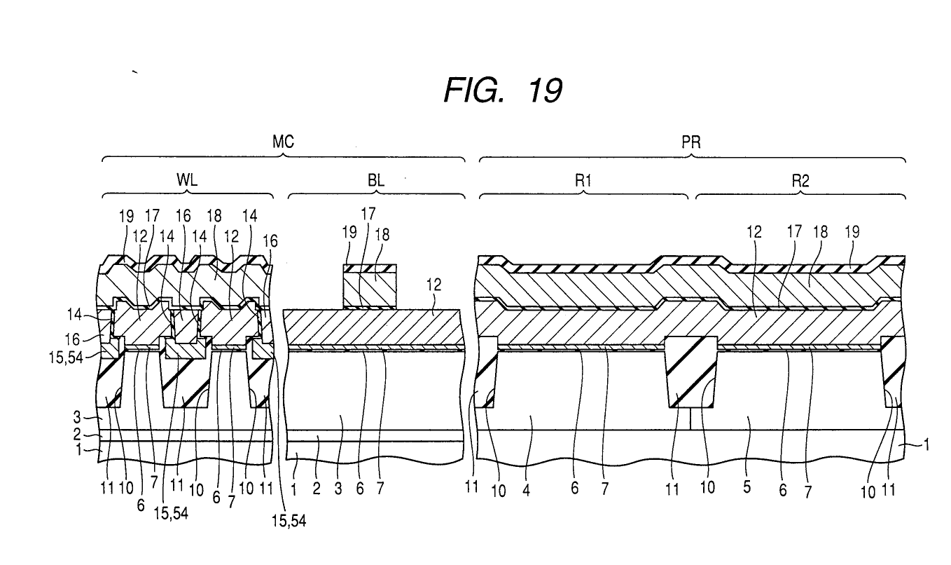

As illustrated in FIG. 19, an ONO film 17 is formed over the surface of the polysilicon film 12 which will be a floating gate electrode, followed by the formation of a polysilicon film 18 which will be a control gate electrode over the ONO film 17. A TEOS silicon oxide film 19 is formed over the polysilicon film 18. A resist pattern (not illustrated) for forming a control gate electrode is then formed over the silicon oxide film 19. With the resist pattern as a mask, the silicon oxide film 19, the polysilicon film 18, and the ONO film 17 are etched to leave a portion of the polysilicon film 18 which will be a control gate electrode as shown in FIG. 19. The resist pattern is then removed.

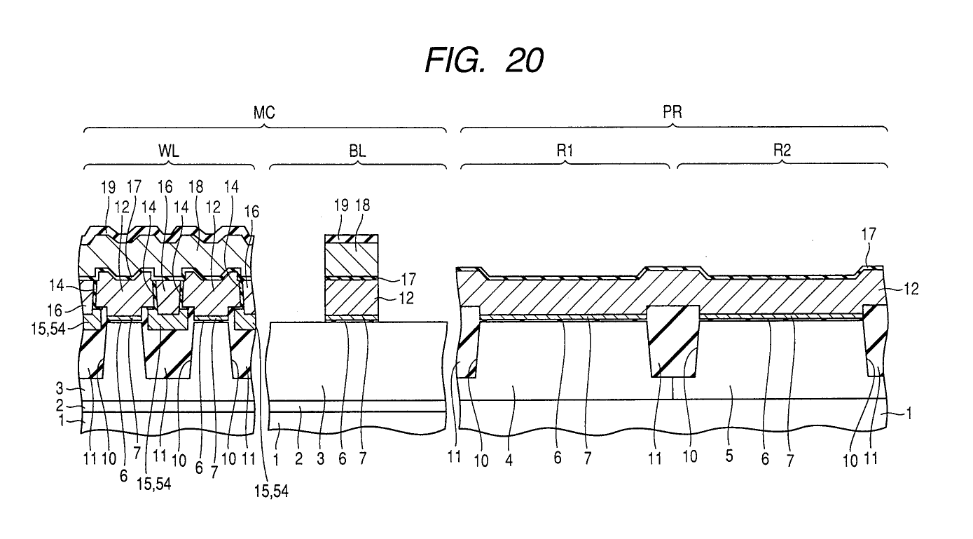

Then, a portion of the silicon oxide film 19 located in the peripheral circuit region PR is removed. Next, as illustrated in FIG. 20, with the silicon oxide film 19 as a mask, the polysilicon film 12 which will be a floating gate electrode is subjected to anisotropic etching to form a floating gate electrode made of the polysilicon film 12 in the memory cell region MC. In the peripheral circuit region PR, on the other hand, the polysilicon film 18 is removed to expose the ONO film 17.

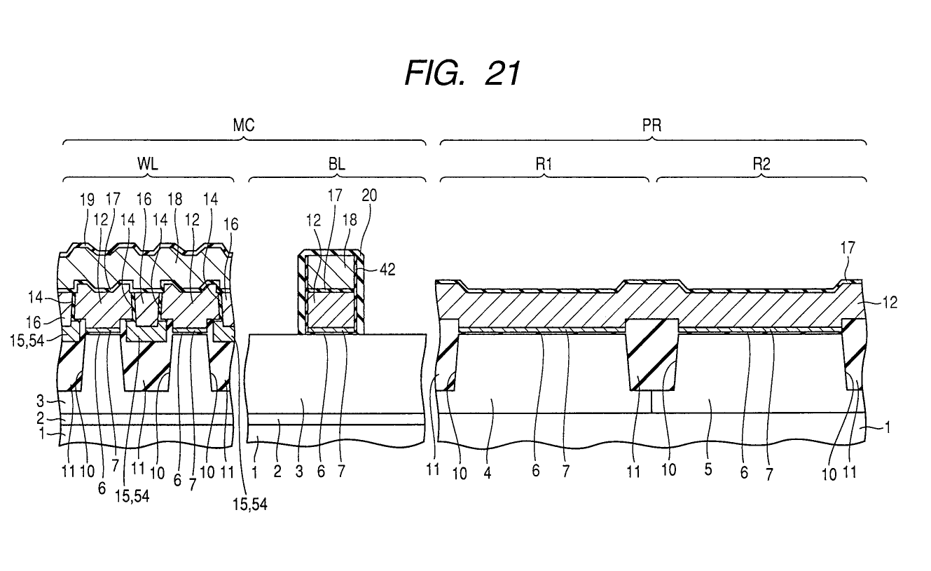

As illustrated in FIG. 21, thermal oxidation treatment is applied onto the side walls of the polysilicon film 12 which will be a floating gate electrode of the memory cell region MC and side walls of the polysilicon film 18 which will be a control gate electrode to form a side-wall oxide film 42. A TEOS silicon oxide film (not illustrated) is formed over the semiconductor substrate 1 to cover therewith the polysilicon films 12 and 18 in the memory cell region MC. Etch-back treatment of the silicon oxide film is performed to form a silicon oxide film 20 as a side-wall oxide film over the side walls of the polysilicon films 12 and 18.

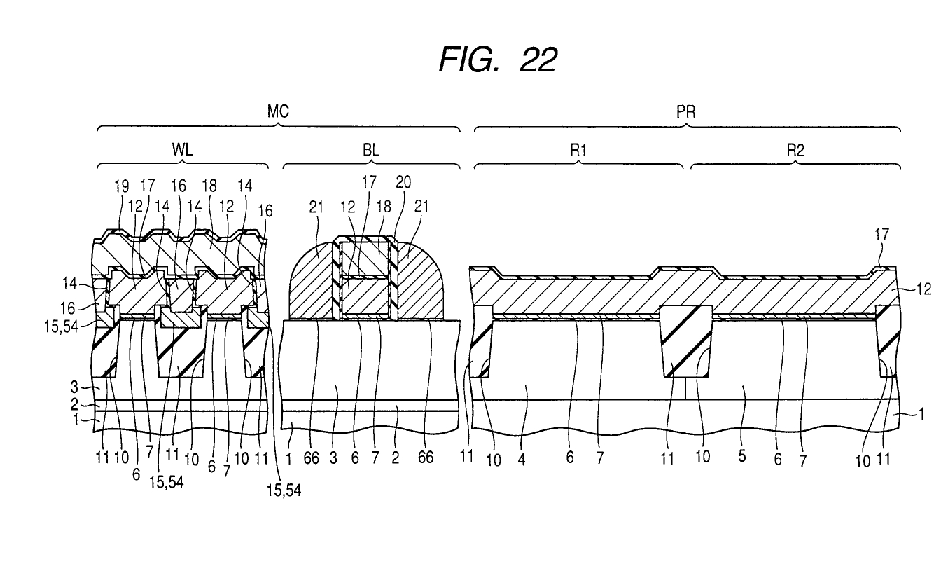

Then, a gate oxide film 66 (refer to FIG. 22) is formed in the memory cell region MC by thermal oxidation. A polysilicon film (not illustrate) which will be an assist gate electrode is formed over the semiconductor substrate 1 to cover the polysilicon film 18 or the like which will be a control gate electrode. As illustrated in FIG. 22, the polysilicon film is anisotropically etched to leave a portion of the polysilicon film 21 located over the side walls of the polysilicon film 12 and the side walls of the polysilicon film 18 via the silicon oxide film 20 and remove the other portion of the polysilicon film.

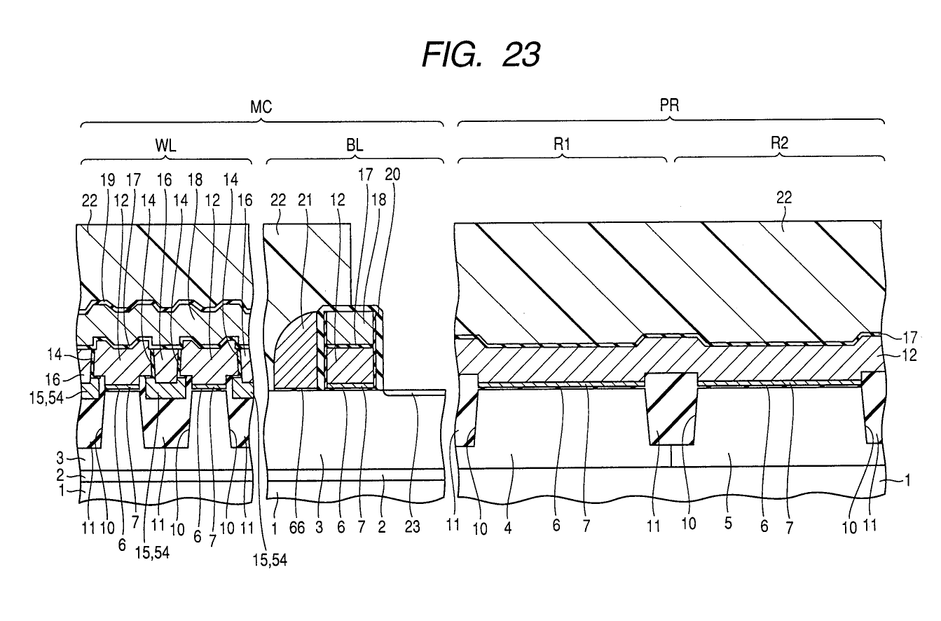

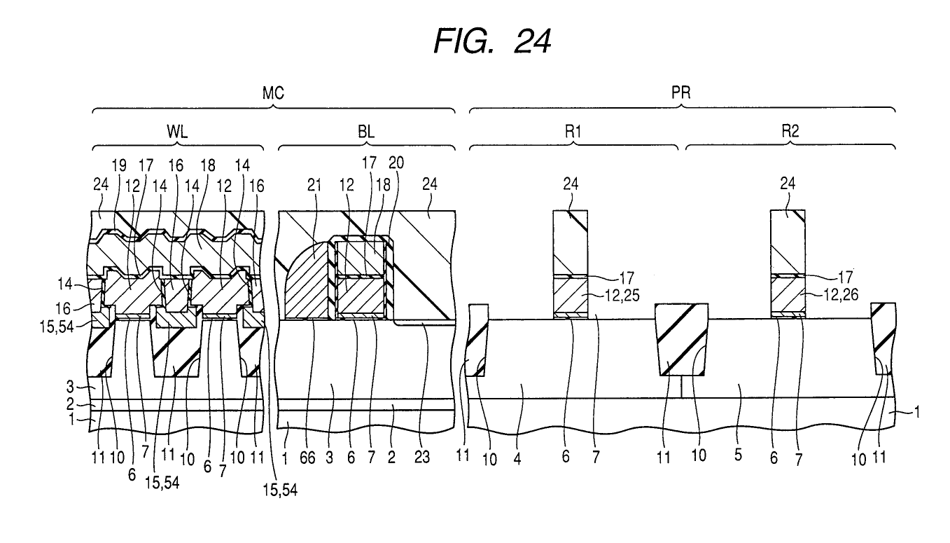

As illustrated in FIG. 23, a resist pattern 22 is formed to cover one of the polysilicon films 21 and 21 located over both of the side walls of the polysilicon film 12 and the polysilicon film 18. With the resulting resist pattern 22 as a mask, etch back is performed to remove the exposed polysilicon film 21 to expose the surface of the semiconductor substrate 1. With the resist pattern 22 and the polysilicon film 18 as a mask, ion injection is performed to form a drain region 23 in the memory cell region MC. Then, the resist pattern 22 is removed.

As illustrated in FIG. 24, a resist pattern 24 for forming a logic gate electrode is formed in the peripheral circuit region PR. With the resist pattern 24 as a mask, the ONO film 17 and the polysilicon film 12 are anisotropically etched to form logic gate electrodes 25 and 26 in the peripheral circuit region PR. Then, the resist pattern 24 is removed.

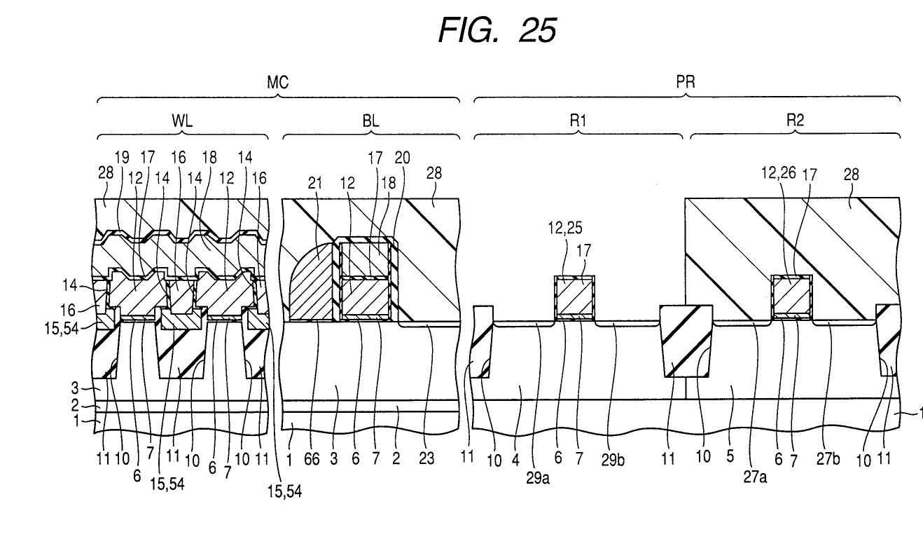

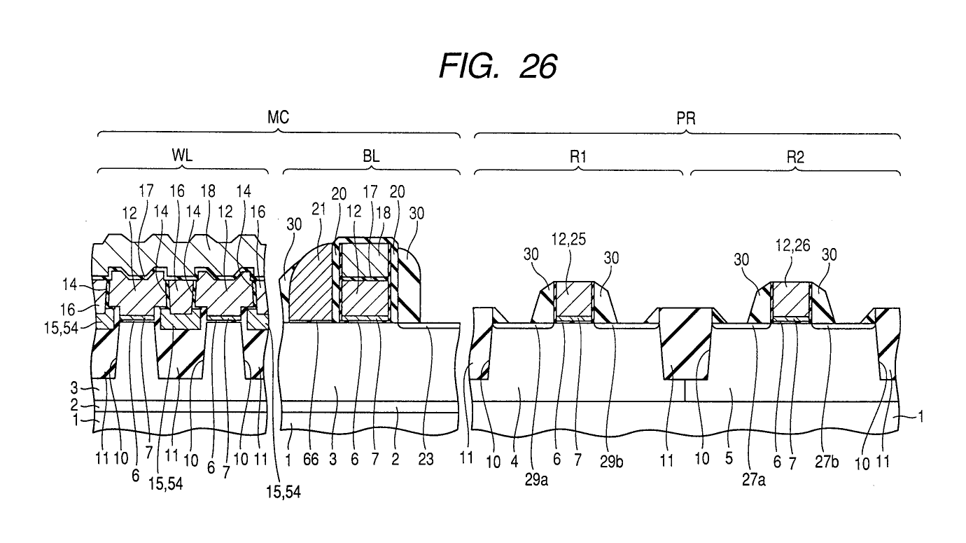

A resist pattern (not illustrated) is then formed to cover a PMOS region R1 therewith and expose an NMOS region therefrom. With the resist pattern as a mask, ion injection is performed to form LDD regions 27a and 27b (refer to FIG. 25) in the NMOS region. Then, the resist pattern is removed. As illustrated in FIG. 25, a resist pattern 28 is then formed to expose the PMOS region R1 therefrom and cover the NMOS region R2 therewith. With the resist pattern 28 as a mask, ion injection is performed to form LDD regions 29a and 29b. Then, the resist pattern 28 is removed.

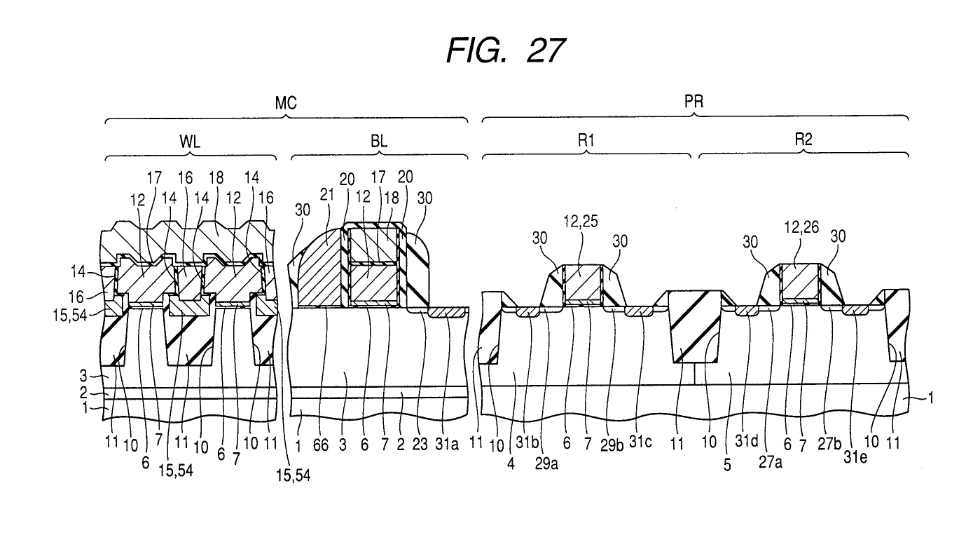

A TEOS silicon oxide film (not illustrated) is then formed over the semiconductor substrate 1 so as to cover therewith the logic gate electrodes 25 and 26. As illustrated in FIG. 26, the silicon oxide film thus formed is then etched back to form a silicon oxide film 30 as a sidewall oxide film over the side surfaces of the logic gate electrodes 25 and 26. Ion injection for forming a source region and a drain region is performed and source regions and drain regions 31a to 31e are formed as illustrated in FIG. 27. A metal silicide layer (not illustrated) such as cobalt silicide is formed by a salicide process in the source regions and drain regions 31a to 31e.

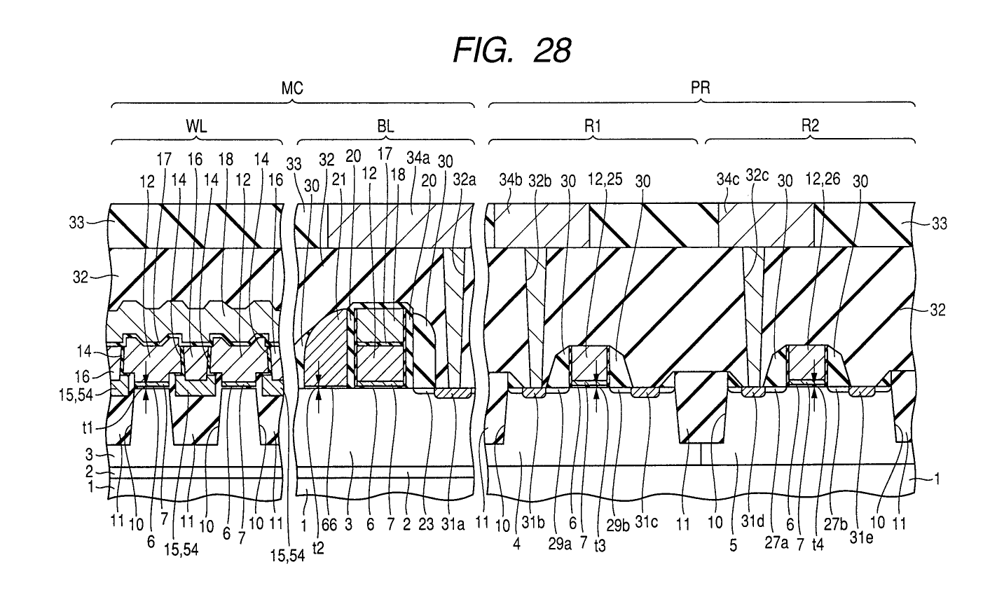

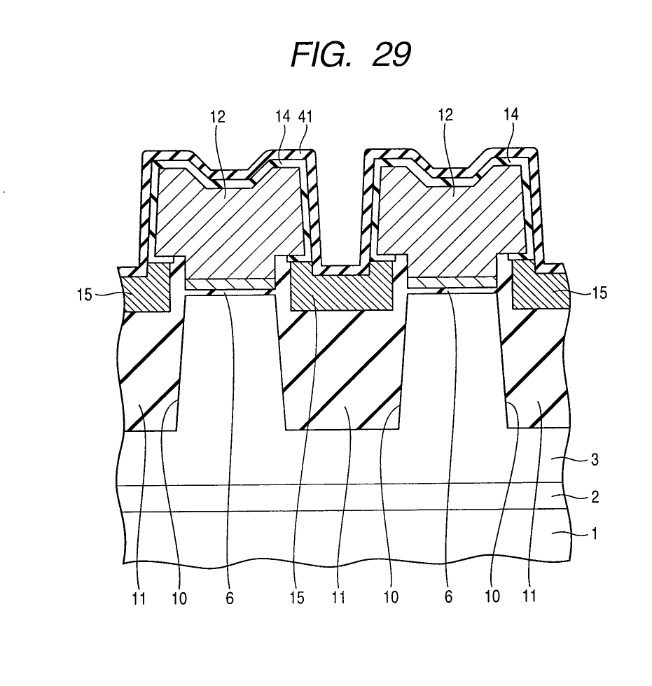

As illustrated in FIG. 28, an interlayer insulating film 32 is formed over the semiconductor substrate 1 to cover the control gate electrode and logic gate electrode 25 and 26. In the interlayer insulating film 32, contact holes 32a, 32b, and 32c are formed to expose therefrom the surface of the metal silicide layer formed over the source regions and drain regions 31a to 31e. Metal plugs are then formed in these contact holes 32a, 32b, and 32c. A silicon oxide film 33 is then formed over the interlayer insulating film 32 to cover the metal plugs. In the silicon oxide film 33, first-level interconnect layers 34a, 34b, and 34c are formed, for example, by the damascene method. Interlayer insulating films and the like are formed further to form second-level interconnect layers and third-level interconnect layers (not illustrated). In such a manner, a principal portion of the flash memory is formed.

In the above manufacturing method of the flash memory, the erase gate electrode 54 is formed in the silicon oxide film 11 filled in the trench 10 in the element isolation region. As illustrated in FIG. 8, in an erase operation, electrons in the floating gate electrode 51 are extracted not into the semiconductor substrate 1 located immediately below the floating gate electrode 51 but into the erase gate electrode 54 in the trench 10. Compared with the substrate FN erase in which electrons are extracted from the floating gate electrode into the semiconductor substrate via a gate oxide film, extraction using the above erase gate electrode enables to suppress deterioration of the gate oxide film and improve the reliability of the flash memory. In addition, the thickness of the gate oxide film 7 can be determined without being limited by the erase rate.

Since the erase gate electrode 54 is formed in the trench 10 in the flash memory of this embodiment, a region or space for the formation of a new erase gate electrode is not necessary, leading to miniaturization of the flash memory.

Compared with a flash memory having an erase gate electrode between two floating gate electrodes adjacent to each other as proposed, for example, in the document (U.S. Pat. No. 6,747,310), formation of the erase gate electrode 54 in the trench 10 can reduce capacitance between the floating gate electrode and the erase gate electrode adjacent to each other, resulting in a corresponding increase in a coupling ratio relating to the control gate electrode. As a result, the operation of the flash memory can be stabilized.

The term “coupling ratio relating to the control gate electrode” means a ratio of capacitance C_{FG} of the control gate electrode and the floating gate electrode to the total capacitance of the capacitance C_{FG}, the capacitance of the floating gate electrode and the semiconductor substrate, the capacitance of the floating gate electrode and the source region or drain region, the capacitance of the floating gate electrode and the erase gate electrode, and the capacitance of the floating gate electrode and the assist gate electrode.

In the flash memory proposed in the above document, resistance of the source region cannot be reduced freely because such an erase gate electrode is formed over the source region. In the present flash memory, on the other hand, the erase gate electrode 54 is formed in the silicon oxide film 11 in the trench 10 so that a metal silicide layer can be formed over the surface of impurity regions (source regions and drain regions 31a to 31e) of a predetermined conductivity type including the source region, making it possible to reduce the resistance.

In the flash memory proposed by the above document, since a predetermined voltage is applied to the erase gate electrode so that a sufficient withstand voltage should be ensured between the erase gate electrode and the source region. In the present flash memory, on the other hand, the erase gate electrode is formed in the silicon oxide film 11 in the trench so that it is not necessary to consider such a withstand voltage between the erase gate electrode and the source region.

In addition, in the above manufacturing method of the flash memory, the assist gate electrode 53 is formed on the side surface of either one of the floating gate electrode 51 or the control gate electrode 52. This enables writing of data by making use of source side injection in a write operation. As a result, a write efficiency can be improved and a write time can be reduced.

The film thickness t1 of the gate oxide film 7 located between the floating gate electrode 51 and the semiconductor substrate 1 is made equal to the film thickness t3 or t4 of the gate oxide film 7 of the transistor in the peripheral circuit region PE (refer to FIG. 28). In the present flash memory, since the write operation is performed by making use of source side injection, the thickness t1 of the gate oxide film 7 immediately below the floating gate electrode 51 can be made relatively thick equal to the thickness t3 or t4 of the gate oxide film 7 of the transistor in the peripheral circuit region PE without causing any substantial influence. On the other hand, the thickness t2 of the gate oxide film 66 (refer to FIG. 22) between the assist gate electrode 53 and the semiconductor substrate 1 is made thinner than the thickness t1 of the gate oxide film 7 immediately below the floating gate electrode 51.

### Modification Example

The above flash memory was described using, as an example of the insulating film 16 covering the erase gate electrode 54, a TEOS silicon oxide film, but a silicon nitride film may be inserted between the erase gate electrode 54 and the silicon oxide film 16.

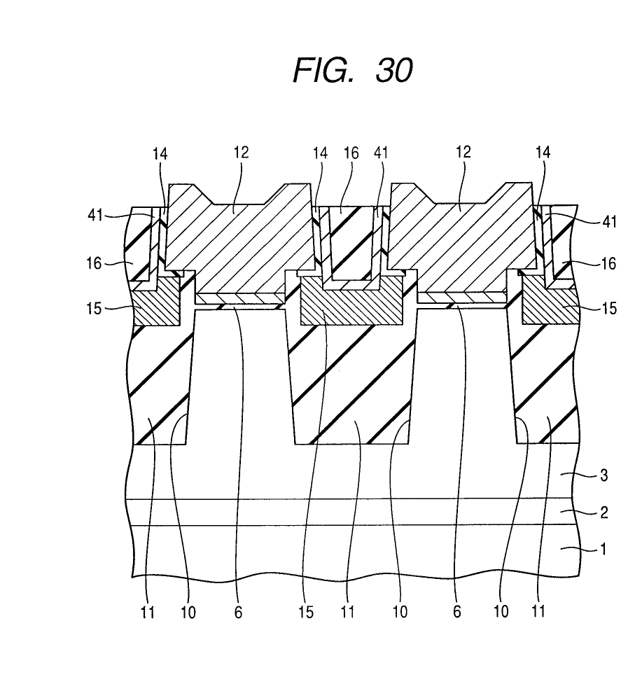

In this case, prior to the formation of the insulating film 16 in the step illustrated in FIG. 17, a silicon nitride film 41 is formed to cover the upper surface of the polysilicon film 15 of the erase gate electrode and the polysilicon film 12 which will be a floating gate electrode. Then, a silicon oxide film which will be the insulating film 16 is formed to cover the silicon nitride film 41. As illustrated in FIG. 30, the silicon oxide film 14, the insulating film 16, and the silicon nitride film 41 are removed while leaving the silicon oxide film 14, the insulating film 16, and the silicon nitride film 41 located between two adjacent polysilicon films 12 and 12 which will be floating gate electrodes and located immediately above the polysilicon film 15 which will be an erase gate electrode.

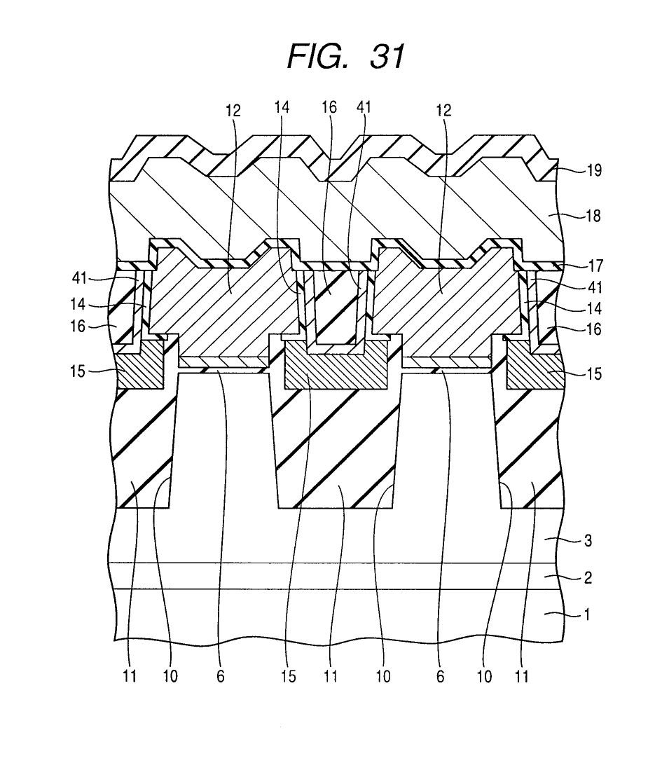

Then, as illustrated in FIG. 31, a polysilicon film 18 which will be a control gate electrode is formed over the polysilicon film 12 which will be a floating gate electrode, while inserting an ONO film 17 therebetween. A silicon oxide film 19 is then formed over the polysilicon film 18, followed by predetermined photoengraving and etching to form the control gate electrode.

The above modified structure has following advantages. First, with regard to the control gate electrode 52 of the flash memory, an increase in the capacitance between the floating gate electrode 51 and the control gate electrode 52 raises a coupling ratio, leading to improvement in write operation characteristics. For the purpose of widening a facing area between the floating gate electrode 51 and the control gate electrode 52 in order to increase the capacitance, it is only necessary to increase an etch back amount of the silicon oxide film 16 formed over the polysilicon film 15 which will be an erase gate electrode to decrease the thickness of the silicon oxide film 16 over the polysilicon film 15 (refer to FIG. 18).

A portion of the silicon oxide film 16 located in a region in which the polysilicon film 18 which will be a control gate electrode has not been formed happens to be excessively etched by overetching when after patterning of the polysilicon film 12 which will be a floating gate electrode, a silicon oxide film 20 is formed (refer to FIG. 21) as a sidewall oxide film over the polysilicon film 12 and the polysilicon film 18 which will be a control gate electrode. If the silicon oxide film 16 is thin, the surface of the polysilicon film 15 which will be an erase gate electrode may presumably be exposed from it.

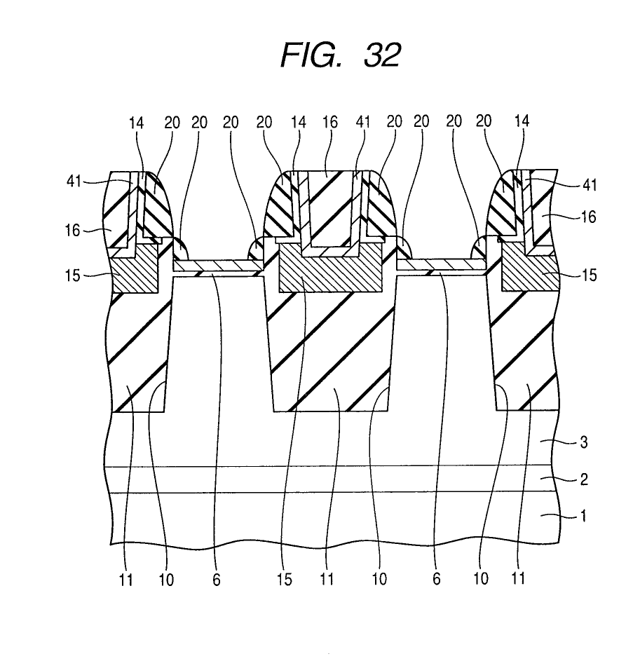

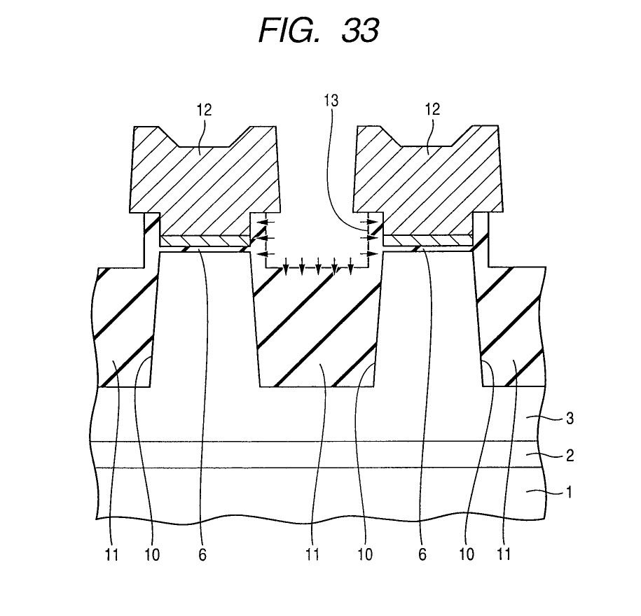

In the flash memory relating to the modification example, since the silicon nitride film 41 different in etching characteristics from the silicon oxide film 16 is formed over the surface of the polysilicon film 15 which will be an erase gate electrode as illustrated in FIG. 32, exposure of the surface of the polysilicon film 15 can be prevented even if the silicon oxide film 16 becomes thin. This makes it possible to certainly prevent disconnection of the erase gate electrode, which will otherwise occur due to etching of a portion of the polysilicon film 15 which will be an erase gate electrode at the time of etch-back treatment (refer to FIG. 22) of the polysilicon film 21 or removal of the polysilicon film 21 (refer to FIG. 23) for the formation of the assist gate electrode.

Further, since the silicon nitride film 41 is formed over the surface of the polysilicon film 15 which will be an erase gate electrode, it is possible to certainly suppress the oxidation of a portion of the polysilicon film 15 which will be an erase gate electrode, which will otherwise occur by thermal oxidation treatment (refer to FIG. 21) upon formation of the side-wall oxide film 42 over the sidewalls of the polysilicon film 12 which will be a floating gate electrode and the sidewalls of the polysilicon film 18 which will be a control gate electrode.

Moreover, in the present flash memory including the flash memory relating to the modification example, the erase gate electrode 51 is formed at a deeper position in the trench 10. This enables to increase an etch-back amount of the polysilicon film 15 which will be the erase gate electrode, thereby increasing the facing area between the floating gate electrode 51 and the control gate electrode 52. As a result, adequate capacitance can be ensured and operation characteristics can be improved.

With regard to the erase gate electrode 54, it is said that when the capacitance between the erase gate electrode 54 and the floating gate electrode 51 is small, their coupling ratio to the total capacitance decreases, leading to improvement in erase operation characteristics.

In the above flash memory, the opening portion 13 for forming the erase gate electrode is formed in the silicon oxide film 11 as illustrated in FIG. 33 first by anisotropically etching the silicon oxide film 11 by dry etching with the polysilicon film 12 which will be a floating gate electrode as a mask and then, carrying out wet etching to etch the silicon oxide film 11 in a lateral direction to form a facing portion of the polysilicon film 12 which will be a floating gate electrode and the polysilicon film 15 which will be an erase gate electrode, thereby forming the opening portion 13.

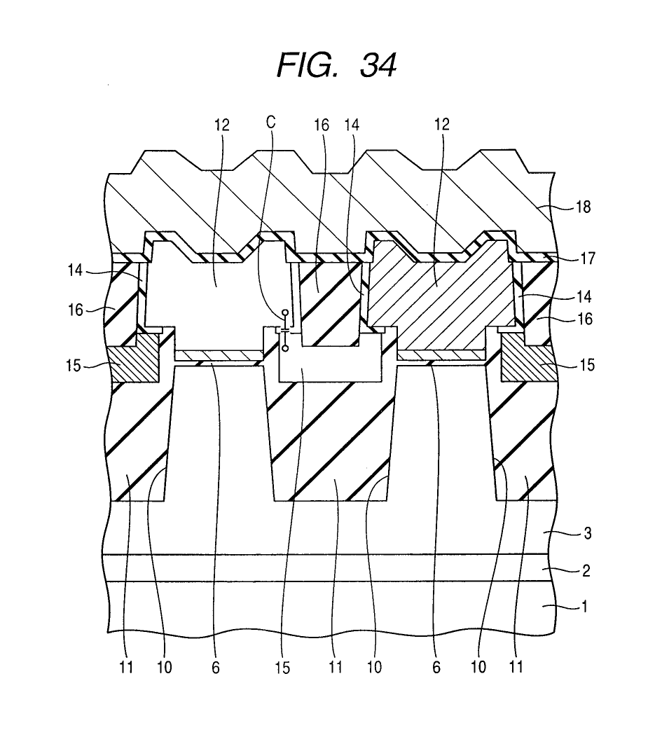

In the opening portion 13, it is possible to stably and precisely form the facing portion by controlling the wet etching amount (arrow) without being influenced by the unevenness formed by dry etching. As illustrated in FIG. 34, this makes it possible to reduce the capacitance C between the erase gate electrode 54 and the floating gate electrode 51, thereby reducing the coupling ratio of the erase gate electrode relative to the total capacitance and at the same time, to suppress variations in the coupling ratio, leading to improvement in erase operation characteristics.

### Embodiment 2

In this embodiment, a NOR type flash memory not equipped with an assist gate electrode will be described. This flash memory has a substantially similar structure to that of the above flash memory except that the former one is not equipped with an assist gate electrode.

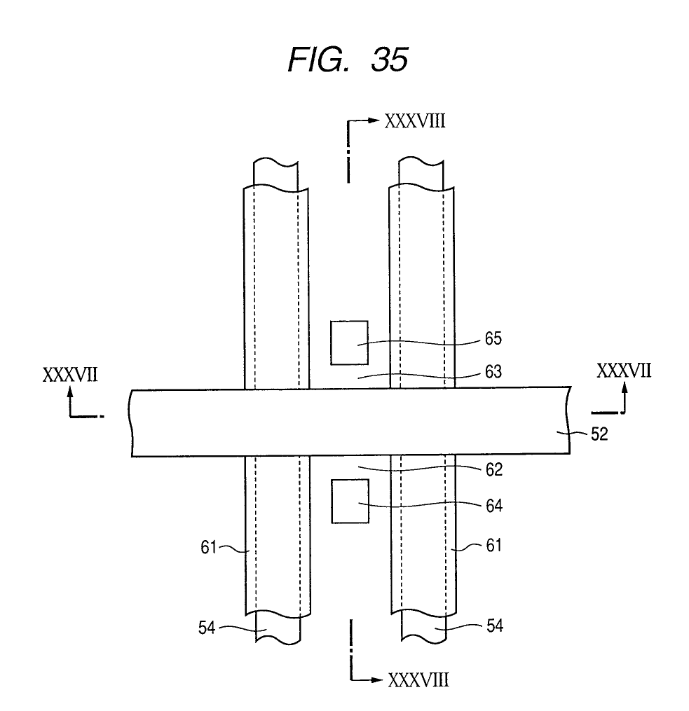

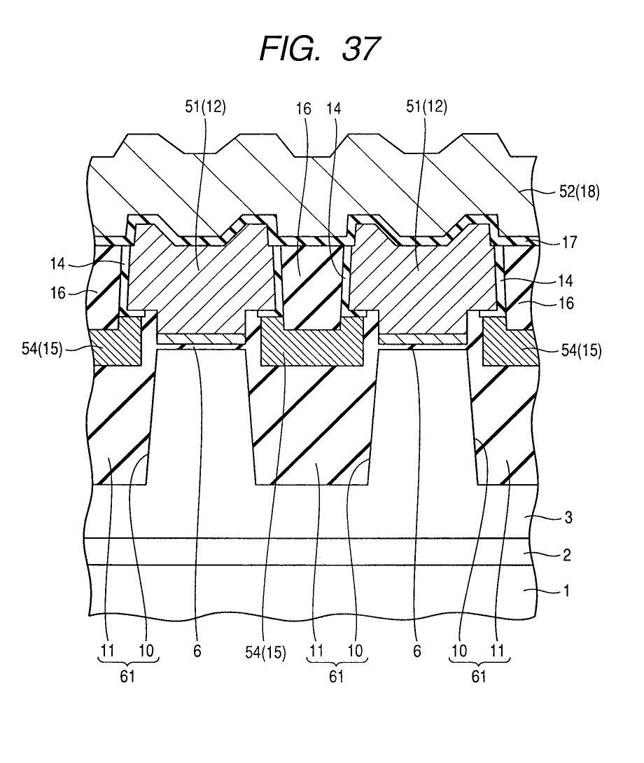

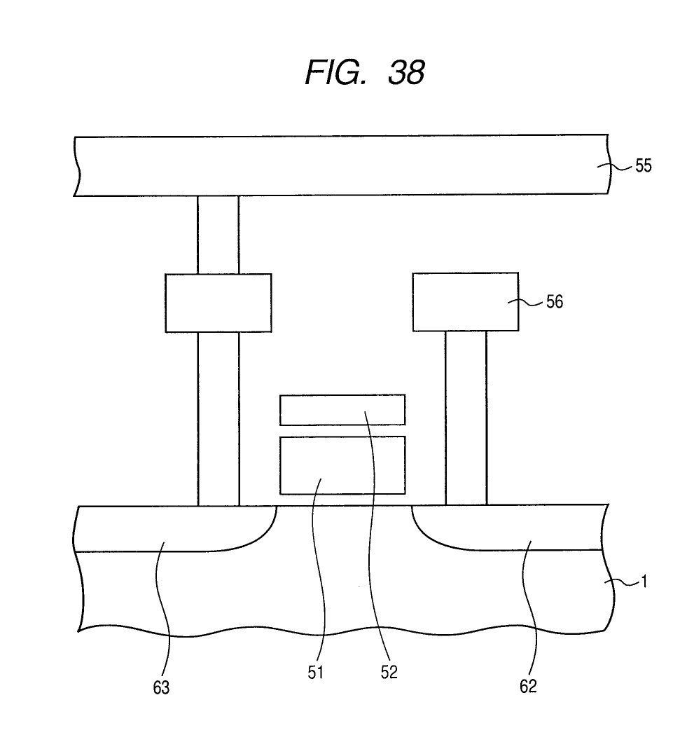

As illustrated in FIGS. 35, 36, 37, and 38, element isolation regions 61 separated from each other with a space therebetween are formed in the principal surface of the semiconductor substrate 1. In a region of the semiconductor substrate sandwiched between two adjacent element isolation regions 61 and 61, an element formation region is formed. In the element isolation region 61, a silicon oxide film 11 is filled in a trench 10 formed in the semiconductor substrate 1 to have a predetermined depth. An erase gate electrode 54 is formed inside the silicon oxide film 11.

A floating gate electrode 51 is formed over the element formation region while inserting a gate oxide film 6 therebetween. A control gate electrode 52 is formed over the floating gate electrode 51 while inserting an ONO film 17 therebetween. A silicon oxide film 14 is formed over the surface of the floating gate electrode 51 and a silicon oxide film 16 is formed between two adjacent floating gate electrodes 51 and 51 to cover the erase gate electrode 54. The control gate electrode 52 is formed in a direction crossing an extending direction of the element isolation region 61.

In one of the element formation regions located on both sides having, therebetween, the floating gate electrode 51 and the control gate electrode 52, a source region 62 is formed, while in the other region, a drain region 63 is formed. A source line 56 is coupled to the source region 62 via a source contact 64. A bit line 55 is coupled to the drain region 63 via a drain contact 65.

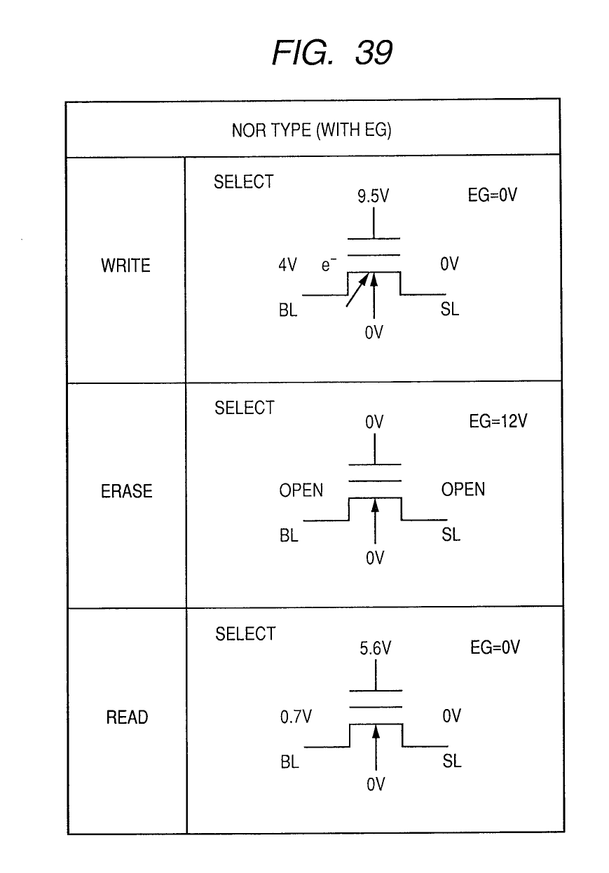

The operation of the above flash memory will next be described. As illustrated in FIG. 39, in a write operation, electrons as data are accumulated in the floating gate electrode (channel hot electrons) by applying 0V to the semiconductor substrate, 9.5V to the control gate electrode of the selected cell, 0V to the source line (SL), 4V to the bit line (BL), and 0V to the erase gate electrode (EG).

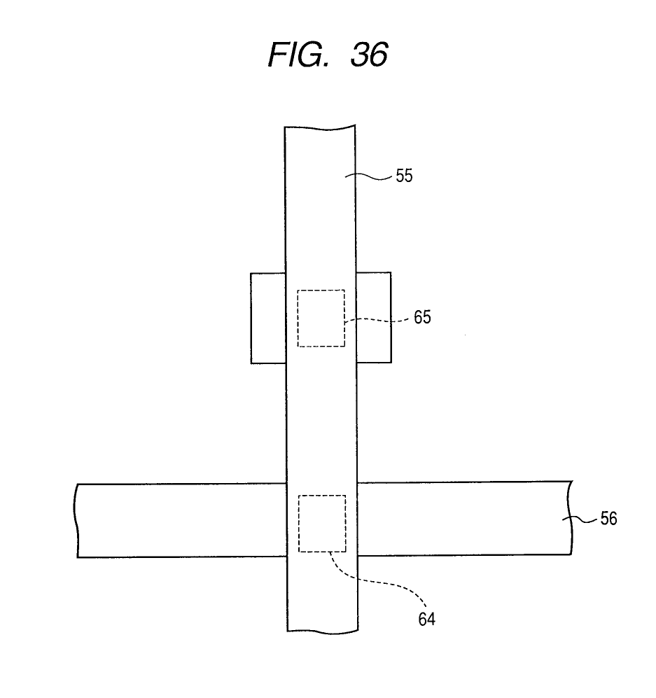

In an erase operation, electrons in the floating gate electrode 51 are extracted into the erase gate electrode 54 formed in the silicon oxide film 11 of the element isolation region 61 by applying 0V to the semiconductor substrate, 0V to the control gate electrode of the selected cell, bringing an open state to the source line (SL) and the bit line (BL), and applying 12V to the erase gate electrode (EG) (refer to FIG. 36).

A read operation is performed by judging whether a current flows or not by applying 0V to the semiconductor substrate, 5.6V to the control gate electrode of the selected cell, 0V to the source line (SL), and 0.7V to the bit line (BL), and 0V to the erase gate electrode (EG).

In the flash memory of Embodiment 2, similar to the flash memory of Embodiment 1, electrons accumulated in the floating gate electrode 51 are extracted into the erase gate electrode 54 buried in the silicon oxide film 11 filled in the trench 10 in an erase operation. Compared with a substrate FN erase in which electrons accumulated in the floating gate electrode are extracted into the semiconductor substrate via the gate oxide film placed immediately below the floating gate electrode, it is therefore possible to suppress the deterioration of the gate oxide film and extend the life of the flash memory. Further, formation of the erase gate electrode 54 in the trench 10 can miniaturize the flash memory because there is no need of a new region or space for the formation of the erase gate electrodes.

In the present flash memory, similar to the flash memory of Embodiment 1, the silicon nitride film may be formed to cover the upper surface of the polysilicon film which will be an erase gate electrode. By forming such a silicon nitride film, it is possible to certainly prevent disconnection of an erase gate electrode which will otherwise occur by etching of a portion of the polysilicon film 15 which will be an erase gate electrode upon etch-back treatment (FIG. 22) of the polysilicon film 21 upon formation of the assist gate electrode or removal of the polysilicon film 21 (FIG. 23). In addition, it is possible to certainly suppress oxidation of a portion of the polysilicon film 15 which will be an erase gate electrode which will otherwise occur by the thermal oxidation treatment for forming the sidewall oxide film 42 over the side walls of the polysilicon film 12 which will be a floating gate electrode and sidewalls of the polysilicon film 18 which will be a control gate electrode.

### Embodiment 3

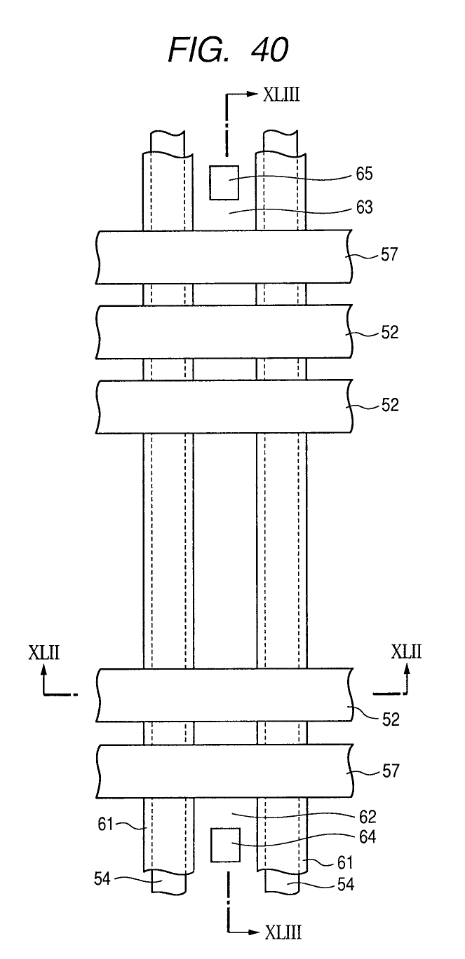

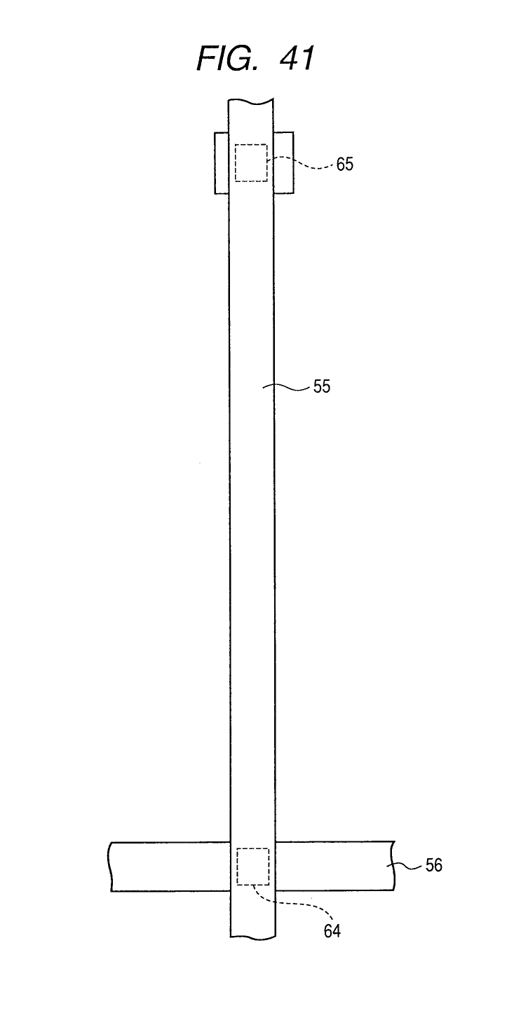

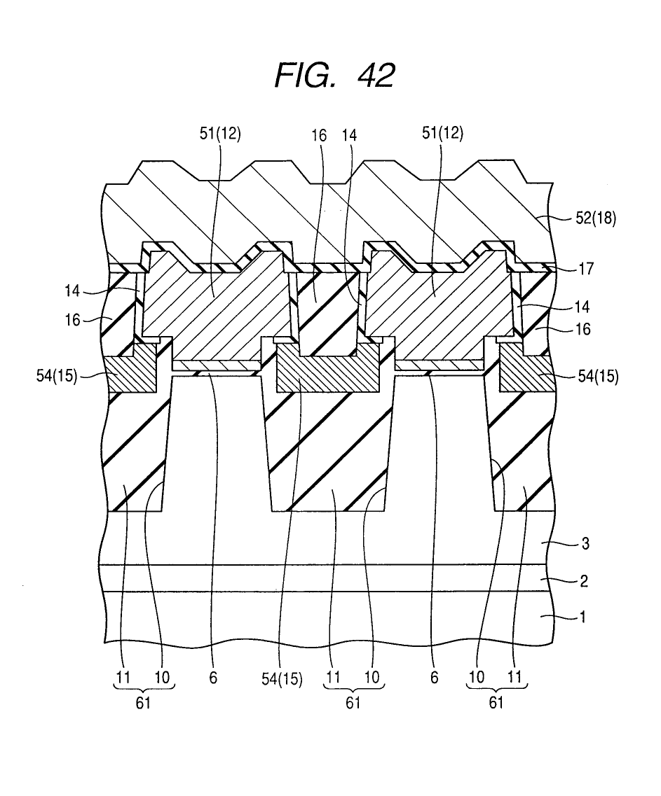

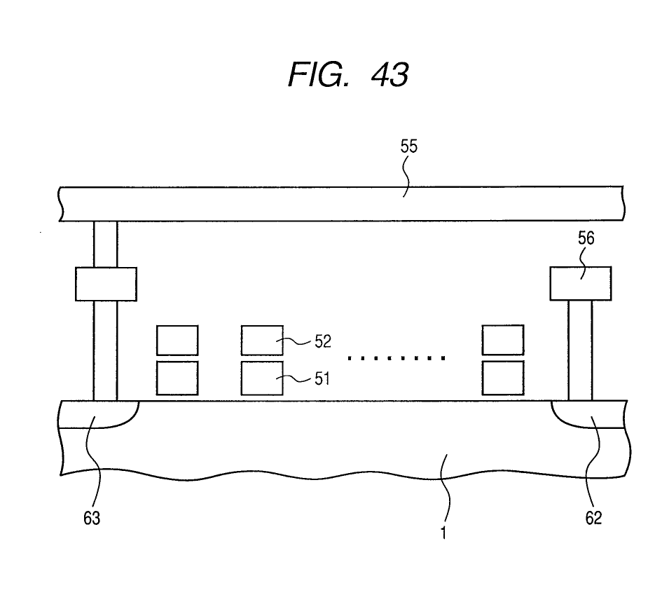

A NAND type flash memory will be described in Embodiment 3. As illustrated in FIGS. 40, 41, 42, and 43, element isolation regions 61 separated from each other with a space therebetween are formed over the principal surface of a semiconductor substrate 1. In a region of the semiconductor substrate sandwiched between two adjacent element isolation regions 61 and 61, an element formation region is formed. In the element isolation region 61, a silicon oxide film 11 is filled in a trench 10 formed in the semiconductor substrate 1 to have a predetermined depth. An erase gate electrode 54 is formed inside the silicon oxide film 11.

Two select gate electrodes 57 separated from each other with a space are formed in an extending direction of the element formation region 61 so as to cross the element formation region. In a region sandwiched between these two select gate electrodes 57, two or more floating gate electrodes 51 separated from each other with a space in an extending direction of the element formation region 61 are formed. Control gate electrodes 52 extending in a direction crossing the extending direction of the element isolation region 61 are formed over the floating gate electrodes 51, respectively, while inserting an ONO film 17 therebetween.

A silicon oxide film 14 located over the surface of the floating gate electrode 51 and a silicon oxide film 16 covering the erase gate electrode 51 are formed between the floating gate electrodes 51 and 51 which are adjacent to each other in an extending direction of the control gate electrode 52.

A source region 62 is formed in the element formation region on a side opposite to, relative to one select gate electrode 57, the side of the other select gate electrode 57. A drain region 63 is formed in the element formation region on a side opposite to, relative to the other select gate electrode 57, the side of the one select gate electrode 57. A source line 56 is coupled to the source region 62 via a source contact 64, while a bit line 55 is coupled to the drain region 63 via a drain contact 65.

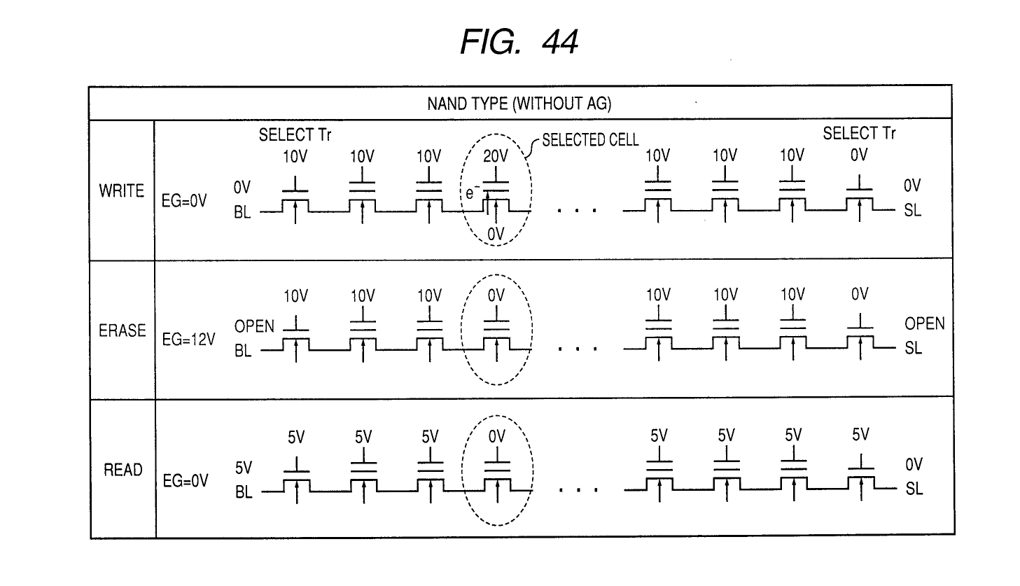

The operation of the above flash memory will next be described. As illustrated in FIG. 44, in a write operation, electrons as data are accumulated from the semiconductor substrate to the floating gate electrode by applying 10 V to the one select gate electrode, 0V to the other select gate electrode, 0V to the semiconductor substrate, 20V to the control gate electrode of the selected cell, 10V to another control gate electrode, 0V to the source line (SL), 0V to the bit line (BL), and 0V to the erase gate electrode (EG).

Next, in an erase operation, electrons in the floating gate electrode 51 are extracted into the erase gate electrode 54 formed in the silicon oxide film 11 in the element isolation region 61 by applying 10V to the one select gate electrode, 0V to the other select gate electrode, 0V to the control gate electrode of the selected cell, and 10V to another control gate electrode, bringing an open state to the source line (SL) and the bit line (BL), and applying 12V to the erase gate electrode (EG) (refer to FIG. 40).

A read operation is performed by judging whether a current flows or not by applying 5V to the one select gate electrode, 5V to the other select gate electrode, 0V to the control gate electrode of the selected cell, 5V to another control gate electrode, 0V to the source line (SL), 5V to the bit line (BL), and 0V to the erase gate electrode (EG).

In an erase operation in the above flash memory, similar to the flash memory described in Embodiment 1, electrons accumulated in the floating gate electrode 51 are extracted into the erase gate electrode 54 formed in the silicon oxide film 11 filled in the trench 10. Compared with substrate FN erase in which electrons accumulated in a floating gate electrode are extracted via a gate oxide film located immediately below the floating gate electrode, deterioration of the gate oxide film can be suppressed and the life of the flash memory can be extended. In addition, formation of the erase gate electrode 54 in the trench 10 enables to miniaturize the flash memory, because a new region or space for the formation of the erase gate electrode is not necessary.

Also in the present flash memory, a silicon nitride film may be formed to cover the upper surface of the polysilicon film which will be an erase gate electrode. Formation of such a silicon nitride film enables to certainly prevent disconnection of the erase gate electrode, which will otherwise occur by the etch-back treatment (FIG. 22) of the polysilicon film 21 upon formation of the assist gate electrode or the etching of a portion of the polysilicon film 15 which will be the erase gate electrode upon removal of the polysilicon film 21 (FIG. 23). In addition, it is possible to certainly suppress oxidation of a portion of the polysilicon film 15 which will be an erase gate electrode, by the thermal oxidation treatment for forming the sidewall oxide film 42 over the side walls of the polysilicon film 12 which will be a floating gate electrode and sidewalls of the polysilicon film 18 which will be a control gate electrode.

The embodiments disclosed herein are intended to be illustrative and not limiting. The scope of the invention is indicated not by the description of the embodiment but by the claims, and it is intended to include all changes which fall within meanings and scopes equivalent to claims.

What is claimed is:

1. A semiconductor memory device, comprising:
a first element isolation region and a second element isolation region which are formed in a first region of a semiconductor substrate having a principal surface, extend in a first direction, and are separated from each other in a second direction crossing the first direction;
a floating gate electrode formed, via a first insulating film, over a predetermined region in an element formation region of the semiconductor substrate sandwiched between the first element isolation region and the second element isolation region;
a control gate electrode which extends in the second direction and is formed over the floating gate electrode via a film stack containing a silicon oxide film and a silicon nitride film;
a pair of impurity regions having a predetermined conductivity type formed in the element formation regions positioned on both sides with the floating gate electrode and the control gate electrode therebetween; and
an erase gate electrode formed along the first direction while being buried in the element isolation region.

2. The semiconductor memory device according to claim 1,
wherein in the element isolation region, a trench having a predetermined depth is formed in the semiconductor substrate, an isolation insulating film is filled in the trench, an opening portion is formed in the isolation insulating film, the erase gate electrode is formed in the opening portion, and a second insulating film is formed over the upper surface of the erase gate electrode.

3. The semiconductor memory device according to claim 1 or 2,
wherein the second insulating film includes: a silicon nitride film formed over at least the upper surface of the erase gate electrode; and a silicon oxide film formed over the silicon nitride film.

4. The semiconductor memory device according to any one of claims 1 to 3, wherein a metal silicide layer is formed over at least one of the impurity regions.

5. The semiconductor memory device according to any one of claims 1 to 4, wherein each cell has a contact portion to be electrically coupled to one of the impurity regions.

6. The semiconductor memory device according to any one of claims 1 to 5, further comprising an access gate electrode formed along the second direction over one side surface of two side surfaces of the floating gate electrode and the control gate electrode stacked one after another.

7. The semiconductor memory device according to claim 6, further comprising a peripheral circuit portion including a transistor formed in a second region of the semiconductor substrate different from the first region,
wherein the thickness of the first insulating film formed between the floating gate electrode and the semiconductor substrate is set equal to the thickness of the gate insulating film of the transistor.

8. The semiconductor memory device according to any one of claims 1 to 5, further comprising:
a first select gate electrode formed to extend in the second direction and cross the element formation region; and
a second select gate electrode formed to have a predetermined distance from the first select gate electrode in the first direction, extend in the second direction, and to cross the element formation region,
wherein a plurality of the floating gate electrodes are formed in a region located between the first select gate electrode and the second select gate electrode while being separated from each other in the first direction,
wherein the control gate electrodes are formed over the floating gate electrodes respectively while inserting the second insulating film therebetween, and
wherein one of the impurity regions is formed on a side opposite to, relative to the first select gate electrode, a side in which the second select gate electrode is located, and
wherein the other impurity region is formed on a side opposite to, relative to the second select gate electrode, a side in which the first select gate electrode is located.
